(19) United States
(12) Patent Application Publication
(10) Pub. No.: US 2025/0206985 A1
(43) Pub. Date: Jun. 26, 2025

(54) POLISHING COMPOSITION

(71) Applicant: FUJIMI INCORPORATED, Kiyosu-shi, Aichi (JP)

(72) Inventors: Anthony Y. KIM, Tualatin, OR (US); Charles POUTASSE, Tualatin, OR (US)

(73) Assignee: FUJIMI INCORPORATED, Kiyosu-shi, Aichi (JP)

(21) Appl. No.: 18/849,430

(22) PCT Filed: Mar. 22, 2023
(86) PCT No.: PCT/JP2023/011115

§ 371 Date: Sep. 20, 2024

Related U.S. Application Data
(60) Provisional application No. 63/326,505, filed on Apr. 1, 2022.

(51) Int. Cl. C09G 1/02; C09K 3/14

(52) U.S. Cl. CPC C09G 1/02; C09K 3/1436

(57) ABSTRACT

Polishing compositions and methods are provided which enable barrier polishing with tunable removal rate ratios for tantalum, cobalt, and copper.

Polishing compositions comprising small (about 12 nm) anionically-modified abrasive particles, a metal corrosion inhibitor, and a phosphate surfactant are capable of achieving Ta to Co selectivities of greater than 10 and Cu to Co selectivities of approximately 1.

This application is based upon the U.S. Provisional Application No. 63/326,505, filed on Apr. 1, 2022, the entire contents of which are incorporated herein by reference.

### TECHNICAL FIELD

The present invention relates to a polishing composition.

### BACKGROUND ART

The following description of the background of the present technology is provided simply as an aid in understanding the present technology and is not admitted to describe or constitute prior art to the present technology.

One of the principal chemical mechanical polishing (CMP) challenges for semiconductor manufacturing is the selective polishing of certain materials. Copper (Cu) is widely used as an interconnect material in semiconductor device fabrication, while tantalum (Ta), cobalt (Co) and combinations thereof, are widely used as barrier materials. It is against this backdrop that the polishing compositions and methods of the present disclosure were developed.

### SUMMARY OF THE INVENTION

The present inventors have found that there exists a need for chemical mechanical polishing compositions that offer tunable Co, Cu, and Ta removal rates and afford high tantalum-to-cobalt removal rate (RR) selectivity (e.g., RRTa/RRCo greater than about 10) and low copper-to-cobalt removal rate selectivity (e.g., RRCu/RRCo approximately equal to 1).

Therefore, an object is to provide a polishing composition capable of improving the polishing rate of Ta as compared with that of Co and polishing Co and Cu at an equivalent rate while satisfying the basic performance of ensuring stability of abrasive grains.

In one aspect, which may be combined with any other aspect or embodiment, the present disclosure relates to a polishing composition, comprising: abrasive grains comprising surface-modified anionic silica particles; a metal corrosion inhibitor; and a surfactant, wherein the polishing composition has a pH of 7 to 10.

In some embodiments, the abrasive grains (also referred to as abrasive particles) have a primary particle size of less than or equal to about 30 nm. In some embodiments, the silica particles have a primary particle size of about 10 nm to about 15 nm. In some embodiments, the abrasive grains are present in the polishing composition at a concentration of about 1.0 wt. % to about 5.0 wt. %. In some embodiments, the surface-modified anionic silica particles comprise oxidized MPS.

In some embodiments, the metal corrosion inhibitor is a triazole present at a concentration of about 0.01 wt. % to about 0.05 wt. %. In some embodiments, the metal corrosion inhibitor comprises benzotriazole.

In some embodiments, the polishing composition further comprises a water-soluble polymer, wherein the water-soluble polymer is a polysaccharide present at a concentration of about 0.01 wt. % to about 0.50 wt. %. In some embodiments, the polysaccharide comprises pullulan, PVA, or PVP.

In some embodiments, the polishing composition further comprises an organic acid, present at a concentration of about 0.01 wt. % to about 0.50 wt. %. In some embodiments, the organic acid comprises citric acid.

In some embodiments, the surfactant is a surfactant comprising a polyoxyalkylene chain. In some embodiments, the surfactant is a phosphate ester-based surfactant. In some embodiments, the surfactant is a phosphate ester-based surfactant comprising a polyoxyalkylene chain. In some embodiments, the surfactant comprises a phosphate surfactant selected from polyoxyethylene alkylphenyl ether phosphates and polyoxyethylene alkenyl ether phosphates. In some embodiments, the surfactant comprises at least one of polyoxyethylene nonyl phenyl phosphate and polyoxyethylene (10) oleyl ether phosphate. In some embodiments, the surfactant is present in the polishing composition at a concentration of about 0.01 wt. % to about 0.3 wt. %.

In some embodiments, the pH of the polishing composition is about 8.0 to about 9.5.

In some embodiments, the polishing composition further comprises an oxidizer, wherein the oxidizer is present in the polishing composition at a concentration of about 1 wt. % to about 5 wt. %.

In another aspect, which may be combined with any other aspect or embodiment, the present disclosure relates to a method of polishing a substrate surface, wherein the substrate surface comprises cobalt and at least one of tantalum or copper, the method comprising: polishing the substrate surface by applying the polishing composition of any one of the above-discussed embodiments to the substrate surface using a polishing pad; wherein the polishing achieves a copper/cobalt polishing rate ratio of between about 0.3 to about 5.

In some embodiments, the polishing achieves a copper/cobalt polishing rate ratio of between about 0.8 to about 1.3. In some embodiments, the polishing achieves a tantalum/cobalt polishing rate ratio of greater than or equal to 10. In some embodiments, the polishing achieves a tantalum/cobalt polishing rate ratio of greater than or equal to 12.

The present disclosure can encompass the following aspects and embodiments.

1. A polishing composition comprising abrasive grains comprising surface-modified anionic silica particles; and a surfactant,
wherein the surfactant is a compound represented by the following formula (I):

[tail-Aₙ-O]ₘ—PO_{q}Hᵣ (I)
wherein the tail is alkenyl or alkylaryl, the alkenyl has 2 to 24 carbon atoms, alkyl of the alkylaryl has 1 to 24 carbon atoms, A is oxyalkylene, the alkylene has 1, 2, or 3 carbon atoms, n is 1 to 20, and m, q, and r are respectively 1, 3, 2; 2, 2, 1; or 3, 1, 0.

2. The polishing composition according to 1., wherein the silica particles have an average primary particle size of less than or equal to 30 nm.

3. The polishing composition according to 1. or 2., further comprising a metal corrosion inhibitor.

4. The polishing composition according to any one of 1. to 3., wherein aryl of the alkylaryl is phenyl.

5. The polishing composition according to any one of 1. to 4., wherein the surface-modified anionic silica particles are colloidal silica having an organic acid immobilized on the surface thereof.

6. The polishing composition according to 3., wherein the metal corrosion inhibitor comprises benzotriazole.

7. The polishing composition according to any one of 1. to 6., comprising a polysaccharide.

8. The polishing composition according to 7., wherein the polysaccharide is glucan.

9. The polishing composition according to 8., wherein the glucan is a glucan.

10. The polishing composition according to any one of 1. to 9., comprising an organic acid having one or more hydroxy groups and two or more carboxyl groups.

11. The polishing composition according to 10., having a pH of 7 to 10.

12. The polishing composition according to any one of 1. to 11., wherein the surfactant is present in the polishing composition at a concentration of 0.01 wt. % to 0.3 wt. %.

13. The polishing composition according to any one of 1. to 12., to be used for polishing a polishing object, wherein the polishing object comprises at least one of cobalt and copper, and tantalum.

14. The polishing composition according to any one of 1. to 13., wherein the polishing composition is designed in such a manner that a ratio of a copper polishing rate (Å/min) to a cobalt polishing rate (Å/min) is 0.3 to 5, and that a ratio of a tantalum polishing rate (Å/min) to the cobalt polishing rate (Å/min) is greater than or equal to 10.

15. A polishing composition comprising abrasive grains comprising surface-modified anionic silica particles; and a surfactant,
wherein the surfactant is a compound represented by the following formula (I):

[tail-Aₙ-O]ₘ—PO_{q}Hᵣ (I)
wherein the tail is alkenyl or alkylaryl, the alkenyl has 2 to 24 carbon atoms, alkyl of the alkylaryl has 1 to 24 carbon atoms, A is oxyalkylene, the alkylene has 1, 2, or 3 carbon atoms, n is 1 to 20, and m, q, and r are respectively 1, 3, 2; 2, 2, 1; or 3, 1, 0, and the polishing composition comprises a polysaccharide, and an organic acid having one or more hydroxy groups and two or more carboxyl groups, and has a pH of 7 to 10.

16. The polishing composition according to any one of 1. to 15., further comprising polyalkylene glycol monoalkyl ether.

Additional aspects and/or embodiments of the invention will be provided, without limitation, in the detailed description of the present technology set forth below. The following detailed description is exemplary and explanatory, but it is not intended to be limiting.

Reference will now be made in detail to some specific embodiments contemplated by the present disclosure. While various embodiments are described herein, it will be understood that it is not intended to limit the present technology to the described embodiments. On the contrary, it is intended to cover alternatives, modifications, and equivalents as may be included within the spirit and scope of the technology as defined by the appended claims.

The present invention will now be described in detail. Herein, the term “X to Y” means that the former and latter numerical values (X and Y) are included as the lower limit and the upper limit, respectively, and means greater than or equal to X and less than or equal to Y. When a plurality of “X to Y” is given, for example, when the term “X1 to Y1, or X2 to Y2” is used, a disclosure using the numerical values as the upper limits, a disclosure using the numerical values as the lower limits, and combinations of these upper and lower limits are all disclosed (namely, which can be legal basis of amendment). Specifically, amendment to “greater than or equal to X1”, amendment to “less than or equal to Y2”, amendment to “less than or equal to X1” amendment to “greater than or equal to Y2”, amendment to “X1 to X2”, and amendment to “X1 to Y2” shall be all regarded as legal. Components comprised in the polishing composition may be comprised in the polishing composition in the form of a combination of two or more kinds thereof unless otherwise stated, and the amount to be used or to be added described here can mean the total amount when the two or more components are used in combination.

Herein, a range can be indicated as being from “about” a specific value and/or to “about” another specific value. When the range is indicated in this manner, in another aspect, the range includes from a specific value, and/or to another specific value. Similarly, when a value is indicated as an approximate value by using the term “about”, it shall be understood that another aspect is formed by using a specific value. It shall also understood that one endpoint of each range is significant in relation to the other endpoint, and independently from the other endpoint. Besides, a large number of values are disclosed herein, and it shall be understood that each value is disclosed herein not only as the value itself but also as “about” the specific value. For example, when a value of “10” is disclosed, a value of “about 10” is also disclosed. It shall be also understood that each constitution unit disposed between two specific constitution units is also disclosed. For example, when 10 and 15 are disclosed, 11, 12, 13, and 14 are also disclosed. The term “about XX” used herein can be XX±10% wherein “XX” is any number. The disclosure of “about XX” used herein encompasses a disclosure of “XX” excluding “about”. The meaning of the phrase “may comprise, or may have” used herein encompasses meaning of “may not comprise, or may not have”, and also can mean that the content in the polishing composition may be less than or equal to 1000 wt. ppm, or less than or equal to 500 wt. ppm when comprised or had.

### Abrasive Grains

Polishing compositions according to the present disclosure comprise abrasive particles suitable for polishing a substrate comprising at least one of Cu, Co, Ta, and one or more dielectric materials (e.g., BD (Black Diamond), SiO₂ (e.g., derived from TEOS (tetraethyl orthosilicate), etc.). In some embodiments, the abrasive particles comprise one or more metal oxide particles, e.g., zirconia, hafnia, alumina, titania, silica, ceria, and any combination thereof. In some embodiments, the abrasive particles comprise colloidal silica, colloidal zirconia, or combinations thereof. In some embodiments, the abrasive particles comprise colloidal silica. In addition, the abrasive particles may be a commercial product, synthetic product, or any combination thereof. In some embodiments, the abrasive particles may be anionic. Within the context of this application, “anionic” particles have a negative surface charge or zeta potential charge at the pH of the polishing composition.

In some embodiments, the abrasive particles are surface-modified by a chemical species covalently attached to the particle surface and having a terminal anionic group. In some embodiments, the abrasive particles comprise colloidal particles which are anionically modified, e.g., by immobilization of an organic acid on the colloidal particle surface.

In some embodiments, greater than or equal to 80 wt. %, greater than or equal to 85 wt. %, greater than or equal to 90 wt. %, greater than or equal to 95 wt. %, or greater than or equal to 99 wt. % of particles comprised in the abrasive grains (abrasive particles) are anionically-modified colloidal silica.

In some embodiments, immobilization of an organic acid on the surface of the abrasive particles (e.g., colloidal silica) in the polishing composition may be carried out by chemically bonding a functional group of the organic acid to the surfaces of the abrasive particles (e.g., colloidal silica). The immobilization of an organic acid on colloidal silica cannot be achieved by only allowing colloidal silica and an organic acid to merely coexist. The immobilization of an organic acid (e.g., a sulfonic acid), on colloidal silica can be carried out, for example, by a method described in E. Cano-Serrano et al., Sulfonic acid-functionalized silica through quantitative oxidation of thiol groups, Chem. Commun. 246-47 (2003), which is hereby incorporated by reference in its entirety. Specifically, colloidal silica with a sulfonic acid immobilized on its surface can be obtained by coupling a silane coupling agent having a thiol group, such as 3-mercaptopropyl trimethoxysilane (“MPS”), to colloidal silica, followed by oxidizing the thiol group with hydrogen peroxide to form a surface-immobilized sulfonic acid (e.g., a surface-bound propane sulfonic acid, such as oxidized MPS).

The immobilization of a carboxylic acid on colloidal silica can be carried out, for example, by a method described in Y. Kazuo et al., Novel Silane Coupling Agents Containing a Photolabile 2-Nitrobenzyl Ester for Introduction of a Carboxy Group on the Surface of Silica Gel, 3 Chem. Lett. 228-29 (2000), which is hereby incorporated by reference in its entirety. Specifically, colloidal silica in which a carboxylic acid is immobilized on its surface can be obtained by coupling a silane coupling agent including photoreactive 2-nitrobenzyl ester to colloidal silica, followed by photoirradiation. These examples of organic acid immobilization on colloidal silica are intended to be exemplary and are not intended to be limiting. Other organic immobilization techniques using different organic acids and different abrasive particle materials (e.g., other than colloidal silica) are intended to be encompassed within the scope of the present disclosure.

In some embodiments, the abrasive particles have an average primary particle size of greater than or equal to about 2 nm, greater than or equal to about 3 nm, greater than or equal to about 4 nm, greater than or equal to about 6 nm, greater than or equal to about 7 nm, greater than or equal to about 8 nm, greater than or equal to about 9 nm, greater than or equal to about 10 nm, greater than or equal to about 11 nm, greater than or equal to about 12 nm, greater than or equal to about 13 nm, greater than or equal to about 14 nm, greater than or equal to about 15 nm, greater than or equal to about 16 nm, greater than or equal to about 17 nm, greater than or equal to about 18 nm, greater than or equal to about 19 nm, greater than or equal to 20 nm, greater than or equal to about 25 nm, greater than or equal to about 30 nm, greater than or equal to about 35 nm, greater than or equal to about 40 nm, greater than or equal to about 45 nm, greater than or equal to about 50 nm, greater than or equal to about 55 nm, greater than or equal to about 60 nm, greater than or equal to about 65 nm, greater than or equal to about 70 nm, greater than or equal to about 75 nm, greater than or equal to about 80 nm, greater than or equal to about 85 nm, greater than or equal to about 90 nm, greater than or equal to about 95 nm, greater than or equal to about 100 nm, greater than or equal to about 110 nm, greater than or equal to about 120 nm, greater than or equal to about 130 nm, greater than or equal to about 140 nm, greater than or equal to about 150 nm, or any range or value therein between.

In some embodiments, the abrasive particles have an average primary particle size of less than or equal to about 150 nm, less than or equal to about 140 nm, less than or equal to about 130 nm, less than or equal to about 120 nm, less than or equal to about 110 nm, less than or equal to about 100 nm, less than or equal to about 95 nm, less than or equal to about 90 nm, less than or equal to about 85 nm, less than or equal to about 80 nm, less than or equal to about 75 nm, less than or equal to about 70 nm, less than or equal to about 65 nm, less than or equal to about 60 nm, less than or equal to about 55 nm, less than or equal to about 50 nm, less than or equal to about 45 nm, less than or equal to about 40 nm, less than or equal to about 35 nm, less than or equal to about 30 nm, less than or equal to about 29 nm, less than or equal to about 28 nm, less than or equal to about 27 nm, less than or equal to about 26 nm, less than or equal to about 25 nm, less than or equal to about 24 nm, less than or equal to about 23 nm, less than or equal to about 22 nm, less than or equal to about 21 nm, less than or equal to about 20 nm, less than or equal to about 19 nm, less than or equal to about 18 nm, less than or equal to about 17 nm, less than or equal to about 16 nm, less than or equal to about 15 nm, less than or equal to about 14 nm, less than or equal to about 13 nm, less than or equal to about 12 nm, less than or equal to about 11 nm, less than or equal to about 10 nm, less than or equal to about 9 nm, less than or equal to about 8 nm, less than or equal to about 7 nm, or any range or value therein between. When the average primary particle size of the abrasive grains becomes smaller, a ratio of the copper polishing rate (Å/min) to the cobalt polishing rate (Å/min) can be efficiently made close to 1, and a ratio of the tantalum polishing rate (Å/min) to the cobalt polishing rate (Å/min) can be made greater than or equal to 10.

In some embodiments, the abrasive particles have an average primary particle size of about 7 nm to about 150 nm, about 7 nm to about 100 nm, about 7 nm to about 90 nm, about 7 nm to about 80 nm, about 7 nm to about 70 nm, about 7 nm to about 60 nm, about 7 nm to about 50 nm, about 7 nm to about 45 nm, about 7 nm to about 40 nm, about 7 nm to about 35 nm, about 7 nm to about 30 nm, about 7 nm to about 25 nm, about 7 nm to about 20 nm, about 7 nm to about 15 nm, about 7 nm to about 14 nm, about 7 nm to about 13 nm, about 7 nm to about 12 nm, about 7 nm to about 11 nm, about 7 nm to about 10 nm, about 10 nm to about 150 nm, about 10 nm to about 100 nm, about 10 nm to about 90 nm, about 10 nm to about 80 nm, about 10 nm to about 70 nm, about 10 nm to about 60 nm, about 10 nm to about 50 nm, about 10 nm to about 45 nm, about 10 nm to about 40 nm, about 10 nm to about 35 nm, about 10 nm to about 30 nm, about 10 nm to about 25 nm, about 10 nm to about 20 nm, about 10 nm to about 15 nm, about 10 nm to about 14 nm, about 10 nm to about 13 nm, about 10 nm to about 12 nm, about 20 nm to about 150 nm, about 20 nm to about 100 nm, about 20 nm to about 90 nm, about 20 nm to about 80 nm, about 20 nm to about 70 nm, about 20 nm to about 60 nm, about 20 nm to about 50 nm, about 20 nm to about 45 nm, about 20 nm to about 40 nm, about 30 nm to about 150 nm, about 30 nm to about 100 nm, about 30 nm to about 90 nm, about 30 nm to about 80 nm, about 30 nm to about 70 nm, about 30 nm to about 60 nm, about 30 nm to about 50 nm, about 30 nm to about 45 nm, about 30 nm to about 40 nm, about 40 nm to about 150 nm, about 40 nm to about 100 nm, about 40 nm to about 90 nm, about 40 nm to about 80 nm, about 40 nm to about 70 nm, about 40 nm to about 60 nm, about 40 nm to about 50 nm, about 50 nm to about 150 nm, about 50 nm to about 100 nm, about 50 nm to about 90 nm, about 50 nm to about 80 nm, about 50 nm to about 70 nm, about 50 nm to about 60 nm, or any range or value therein. In some embodiments, the abrasive particles have an average primary particle size of about 1 nm to about 30 nm, about 2 nm to about 28 nm, about 3 nm to about 26 nm, about 4 nm to about 24 nm, about 5 nm to about 22 nm, about 6 nm to about 20 nm, about 7 nm to about 18 nm, about 8 nm to about 16 nm, about 9 nm to about 15 nm, about 9 nm to about 14 nm, about 10 nm to about 13 nm, or any range or value therein.

In some embodiments, the abrasive particles have a mean particle diameter of greater than or equal to about 10 nm, greater than or equal to about 11 nm, greater than or equal to about 12 nm, greater than or equal to about 13 nm, greater than or equal to about 14 nm, greater than or equal to about 15 nm, greater than or equal to about 16 nm, greater than or equal to about 17 nm, greater than or equal to about 18 nm, greater than or equal to about 19 nm, greater than or equal to about 20 nm, greater than or equal to about 21 nm, greater than or equal to about 22 nm, greater than or equal to about 23 nm, greater than or equal to about 24 nm, greater than or equal to about 25 nm, greater than or equal to about 30 nm, greater than or equal to about 35 nm, greater than or equal to about 40 nm, greater than or equal to about 45 nm, greater than or equal to about 50 nm, greater than or equal to about 55 nm, greater than or equal to about 60 nm, greater than or equal to about 65 nm, greater than or equal to about 70 nm, greater than or equal to about 75 nm, greater than or equal to about 80 nm, greater than or equal to about 85 nm, greater than or equal to about 90 nm, greater than or equal to about 95 nm, greater than or equal to about 100 nm, greater than or equal to about 110 nm, greater than or equal to about 120 nm, greater than or equal to about 130 nm, greater than or equal to about 140 nm, greater than or equal to about 150 nm, greater than or equal to about 160 nm, greater than or equal to about 170 nm, greater than or equal to about 180 nm, greater than or equal to about 190 nm, greater than or equal to about 200 nm, greater than or equal to about 250 nm, greater than or equal to about 300 nm, or any range or value therein between.

In some embodiments, the abrasive particles have a mean particle diameter of less than or equal to about 300 nm, less than or equal to about 250 nm, less than or equal to about 200 nm, less than or equal to about 190 nm, less than or equal to about 180 nm, less than or equal to about 170 nm, less than or equal to about 160 nm, less than or equal to about 150 nm, less than or equal to about 140 nm, less than or equal to about 130 nm, less than or equal to about 120 nm, less than or equal to about 110 nm, less than or equal to about 100 nm, less than or equal to about 95 nm, less than or equal to about 90 nm, less than or equal to about 85 nm, less than or equal to about 80 nm, less than or equal to about 75 nm, less than or equal to about 70 nm, less than or equal to about 65 nm, less than or equal to about 60 nm, less than or equal to about 55 nm, less than or equal to about 50 nm, less than or equal to about 45 nm, less than or equal to about 40 nm, less than or equal to about 35 nm, less than or equal to about 30 nm, less than or equal to about 29 nm, less than or equal to about 28 nm, less than or equal to about 27 nm, less than or equal to about 26 nm, less than or equal to about 25 nm, less than or equal to about 24 nm, less than or equal to about 23 nm, less than or equal to about 22 nm, less than or equal to about 21 nm, less than or equal to about 20 nm, less than or equal to about 19 nm, less than or equal to about 18 nm, less than or equal to about 17 nm, less than or equal to about 16 nm, less than or equal to about 15 nm, less than or equal to about 10 nm, or any range or value therein between.

In some embodiments, the abrasive particles have a mean particle diameter of about 10 nm to about 300 nm, about 10 nm to about 200 nm, about 10 nm to about 150 nm, about 10 nm to about 100 nm, about 10 nm to about 90 nm, about 10 nm to about 80 nm, about 10 nm to about 70 nm, about 10 nm to about 60 nm, about 10 nm to about 50 nm, about 10 nm to about 45 nm, about 10 nm to about 40 nm, about 10 nm to about 35 nm, about 10 nm to about 30 nm, about 10 nm to about 25 nm, about 10 nm to about 24 nm, about 10 nm to about 23 nm, about 10 nm to about 22 nm, about 10 nm to about 21 nm, about 10 nm to about 20 nm, about 10 nm to about 19 nm, about 10 nm to about 18 nm, about 10 nm to about 17 nm, about 10 nm to about 16 nm, about 10 nm to about 15 nm, about 10 nm to about 14 nm, about 10 nm to about 13 nm, about 10 nm to about 12 nm, about 20 nm to about 300 nm, about 20 nm to about 200 nm, about 20 nm to about 150 nm, about 20 nm to about 100 nm, about 20 nm to about 90 nm, about 20 nm to about 80 nm, about 20 nm to about 70 nm, about 20 nm to about 60 nm, about 20 nm to about 50 nm, about 20 nm to about 45 nm, about 20 nm to about 40 nm, about 20 nm to about 35 nm, about 20 nm to about 30 nm, about 20 nm to about 25 nm, about 20 nm to about 24 nm, about 20 nm to about 23 nm, about 20 nm to about 22 nm, about 30 nm to about 300 nm, about 30 nm to about 200 nm, about 30 nm to about 150 nm, about 30 nm to about 100 nm, about 30 nm to about 90 nm, about 30 nm to about 80 nm, about 30 nm to about 70 nm, about 30 nm to about 60 nm, about 30 nm to about 50 nm, about 30 nm to about 45 nm, about 30 nm to about 40 nm, about 40 nm to about 300 nm, about 40 nm to about 200 nm, about 40 nm to about 150 nm, about 40 nm to about 100 nm, about 40 nm to about 90 nm, about 40 nm to about 80 nm, about 40 nm to about 70 nm, about 40 nm to about 60 nm, about 40 nm to about 50 nm, about 50 nm to about 300 nm, about 50 nm to about 200 nm, about 50 nm to about 150 nm, about 50 nm to about 100 nm, about 50 nm to about 90 nm, about 50 nm to about 80 nm, about 50 nm to about 70 nm, about 50 nm to about 60 nm, or any range or value therein.

In some embodiments, the abrasive particles have a mean particle diameter of about 7 nm to about 39 nm, about 8 nm to about 35 nm, about 9 nm to about 31 nm, about 11 nm to about 33 nm, about 13 nm to about 31 nm, about 15 nm to about 29 nm, about 16 nm to about 27 nm, about 17 nm to about 25 nm, or any range or value therein.

In some embodiment, the abrasive particles have a degree of association of greater than 1.0, greater than or equal to 1.1, greater than or equal to 1.2, greater than or equal to 1.3, greater than or equal to 1.4, or greater than or equal to 1.5. In some embodiment, the abrasive particles have a degree of association of less than or equal to 3.0, less than or equal to 2.5, less than or equal to 2.4, less than or equal to 2.3, less than or equal to 2.2, less than or equal to 2.1, less than or equal to 2.0, less than or equal to 1.9, or less than or equal to 1.8.

In some embodiments, the abrasive particles are present in the composition at a concentration by weight, relative to the total weight of the composition, of greater than or equal to about 0.01 wt. %, greater than or equal to about 0.05 wt. %, greater than or equal to about 0.1 wt. %, greater than or equal to about 0.15 wt. %, greater than or equal to about 0.2 wt. %, greater than or equal to about 0.25 wt. %, greater than or equal to about 0.3 wt. %, greater than or equal to about 0.35 wt. %, greater than or equal to about 0.4 wt. %, greater than or equal to about 0.45 wt. %, greater than or equal to about 0.5 wt. %, greater than or equal to about 0.55 wt. %, greater than or equal to about 0.60 wt. %, greater than or equal to about 0.65 wt. %, greater than or equal to about 0.7 wt. %, greater than or equal to about 0.75 wt. %, greater than or equal to about 0.8 wt. %, greater than or equal to about 0.85 wt. %, greater than or equal to about 0.9 wt. %, greater than or equal to about 0.95 wt. %, greater than or equal to about 1.0 wt. %, greater than or equal to about 1.1 wt. %, greater than or equal to about 1.2 wt. %, greater than or equal to about 1.3 wt. %, greater than or equal to about 1.4 wt. %, greater than or equal to about 1.5 wt. %, greater than or equal to about 1.6 wt. %, greater than or equal to about 1.7 wt. %, greater than or equal to about 1.8 wt. %, greater than or equal to about 1.9 wt. %, greater than or equal to about 2.0 wt. %, greater than or equal to about 2.5 wt. %, greater than or equal to about 3.0 wt. %, greater than or equal to about 3.5 wt. %, greater than or equal to about 4.0 wt. %, greater than or equal to about 4.5 wt. %, greater than or equal to about 5.0 wt. %, greater than or equal to about 5.5 wt. %, greater than or equal to about 6.0 wt. %, greater than or equal to about 6.5 wt. %, greater than or equal to about 7.0 wt. %, greater than or equal to about 7.5 wt. %, greater than or equal to about 8.0 wt. %, greater than or equal to about 8.5 wt. %, greater than or equal to about 9.0 wt. %, greater than or equal to about 9.5 wt. %, greater than or equal to about 10.0 wt. %, or any range or value therein between.

In some embodiments, the abrasive particles are present in the composition at a concentration by weight, relative to the total weight of the composition, of less than or equal to about 10.0 wt. %, less than or equal to about 9.5 wt. %, less than or equal to about 9.0 wt. %, less than or equal to about 8.5 wt. %, less than or equal to about 8.0 wt. %, less than or equal to about 7.5 wt. %, less than or equal to about 7.0 wt. %, less than or equal to about 6.5 wt. %, less than or equal to about 6.0 wt. %, less than or equal to about 5.5 wt. %, less than or equal to about 5.0 wt. %, less than or equal to about 4.5 wt. %, less than or equal to about 4.0 wt. %, less than or equal to about 3.5 wt. %, less than or equal to about 3.0 wt. %, less than or equal to about 2.5 wt. %, less than or equal to about 2.0 wt. %, less than or equal to about 1.9 wt. %, less than or equal to about 1.8 wt. %, less than or equal to about 1.7 wt. %, less than or equal to about 1.6 wt. %, less than or equal to about 1.5 wt. %, less than or equal to about 1.4 wt. %, less than or equal to about 1.3 wt. %, less than or equal to about 1.2 wt. %, less than or equal to about 1.1 wt. %, less than or equal to about 1.0 wt. %, less than or equal to about 0.95 wt. %, less than or equal to about 0.9 wt. %, less than or equal to about 0.85 wt. %, less than or equal to about 0.8 wt. %, less than or equal to about 0.75 wt. %, less than or equal to about 0.7 wt. %, less than or equal to about 0.65 wt. %, less than or equal to about 0.6 wt. %, less than or equal to about 0.55 wt. %, less than or equal to about 0.5 wt. %, less than or equal to about 0.45 wt. %, less than or equal to about 0.4 wt. %, less than or equal to about 0.35 wt. %, less than or equal to about 0.3 wt. %, less than or equal to about 0.25 wt. %, less than or equal to about 0.2 wt. %, less than or equal to about 0.15 wt. %, less than or equal to about 0.1 wt. %, or any range or value therein between.

In some embodiments, the abrasive particles are present in the composition at a concentration by weight, relative to the total weight of the composition, of about 0.1 wt. % to about 10.0 wt. %, about 0.2 wt. % to about 10.0 wt. %, about 0.3 wt. % to about 10.0 wt. %, about 0.4 wt. % to about 10.0 wt. %, about 0.5 wt. % to about 10.0 wt. %, about 0.6 wt. % to about 10.0 wt. %, about 0.7 wt. % to about 10.0 wt. %, about 0.8 wt. % to about 10.0 wt. %, about 0.9 wt. % to about 10.0 wt. %, about 1.0 wt. % to about 10.0 wt. %, about 2 wt. % to about 10.0 wt. %, about 3 wt. % to about 10.0 wt. %, about 4 wt. % to about 10.0 wt. %, about 5 wt. % to about 10.0 wt. %, about 0.1 wt. % to about 5 wt. %, about 0.2 wt. % to about 5 wt. %, about 0.3 wt. % to about 5 wt. %, about 0.4 wt. % to about 5 wt. %, about 0.5 wt. % to about 5 wt. %, about 0.6 wt. % to about 5 wt. %, about 0.7 wt. % to about 5 wt. %, about 0.8 wt. % to about 5 wt. %, about 0.9 wt. % to about 5 wt. %, about 1.0 wt. % to about 5 wt. %, about 0.1 wt. % to about 2.0 wt. %, about 0.2 wt. % to about 2.0 wt. %, about 0.3 wt. % to about 2.0 wt. %, about 0.4 wt. % to about 2.0 wt. %, about 0.5 wt. % to about 2.0 wt. %, about 0.6 wt. % to about 2.0 wt. %, about 0.7 wt. % to about 2.0 wt. %, about 0.8 wt. % to about 2.0 wt. %, about 0.9 wt. % to about 2.0 wt. %, about 1.0 wt. % to about 2.0 wt. %, about 0.1 wt. % to about 1.0 wt. %, about 0.2 wt. % to about 1.0 wt. %, about 0.3 wt. % to about 1.0 wt. %, about 0.4 wt. % to about 1.0 wt. %, about 0.5 wt. % to about 1.0 wt. %, about 0.6 wt. % to about 1.0 wt. %, about 0.1 wt. % to about 0.9 wt. %, about 0.1 wt. % to about 0.8 wt. %, about 0.1 wt. % to about 0.7 wt. %, about 0.2 wt. % to about 0.9 wt. %, about 0.2 wt. % to about 0.8 wt. %, about 0.2 wt. % to about 0.7 wt. %, about 0.3 wt. % to about 0.9 wt. %, about 0.3 wt. % to about 0.8 wt. %, about 0.3 wt. % to about 0.7 wt. %, about 0.4 wt. % to about 0.9 wt. %, about 0.4 wt. % to about 0.8 wt. %, about 0.4 wt. % to about 0.7 wt. %, about 0.5 wt. % to about 0.9 wt. %, about 0.5 wt. % to about 0.8 wt. %, about 0.5 wt. % to about 0.7 wt. %, about 0.6 wt. % to about 0.9 wt. %, about 0.6 wt. % to about 0.8 wt. %, or any range or value therein. In some embodiments, the abrasive particles are present in the composition at a concentration by weight, relative to the total weight of the composition, of about 0.01 wt. % to about 7.0 wt. %, about 0.03 wt. % to about 6.0 wt. %, about 0.05 wt. % to about 5.0 wt. %, about 0.07 wt. % to about 4.7 wt. %, about 0.09 wt. % to about 4.6 wt. %, about 0.1 wt. % to about 4.6 wt. %, about 0.3 wt. % to about 4.5 wt. %, about 0.5 wt. % to about 4.4 wt. %, about 0.6 wt. % to about 4.4 wt. %, about 0.7 wt. % to about 4.3 wt. %, about 0.8 wt. % to about 4.2 wt. %, about 0.9 wt. % to about 4.1 wt. %, about 1.0 wt. % to about 4.0 wt. %, about 1.1 wt. % to about 3.9 wt. %, about 1.2 wt. % to about 3.8 wt. %, about 1.3 wt. % to about 3.7 wt. %, about 1.4 wt. % to about 3.6 wt. %, about 1.5 wt. % to about 3.5 wt. %, about 1.6 wt. % to about 3.4 wt. %, about 1.7 wt. % to about 3.3 wt. %, about 1.8 wt. % to about 3.2 wt. %, about 1.8 wt. % to about 3.1 wt. %, about 1.8 wt. % to about 3.0 wt. %, about 1.8 wt. % to about 2.9 wt. %, about 1.8 wt. % to about 2.8 wt. %, or about 1.8 wt. % to about 2.7 wt. %.

In some embodiments, the abrasive particles (e.g., colloidal silica or anionically-modified colloidal silica) have a negative charge under pH conditions used in the polishing compositions of the present disclosure. In some embodiments, the abrasive particles (e.g., colloidal silica or anionically-modified colloidal silica) have a negative charge under basic pH conditions, e.g., at pH of 8, 8.5, 9, 9.5, or 10. In some embodiments, the zeta potential of the abrasive particles is equal to or more negative than −1 mV, −2 mV, −5 mV, −10 mV, −15 mV, −20 mV, −25 mV, −30 mV, −35 mV, or −40 mV, or any range or value therein between. In some embodiments, the zeta potential of the anionically-modified abrasive particles is a greater negative charge (i.e., is more negative) than a corresponding unmodified abrasive particle (e.g., unmodified colloidal silica) at the same pH conditions. In some embodiments, the zeta potential of the abrasive particles (e.g., colloidal silica, or anionically-modified colloidal silica) in the polishing composition of the present disclosure at the pH of greater than 7.0 and less than or equal to 14, 7.5 to 12, 8.0 to 10, or 8.5 to 10 is equal to or more negative than −1 mV, equal to or more negative than −2 mV, equal to or more negative than −5 mV, equal to or more negative than −10 mV, equal to or more negative than −15 mV, equal to or more negative than −20 mV, equal to or more negative than −25 mV, equal to or more negative than −30 mV, equal to or more negative than −35 mV, or equal to or more negative than −40 mV. In some embodiments, the zeta potential of the abrasive particles (e.g., colloidal silica, or anionically-modified colloidal silica) is equal to or more than −50 mV.

### Surfactant (e.g., Anionic Surfactant)

In some embodiments, the polishing compositions according to the present disclosure comprise one or more anionic surfactants, (e.g., phosphate surfactants). By way of non-limiting example, the anionic surfactant comprises a polyoxyethylene alkyl ether phosphate. In some embodiments, the polyoxyethylene alkyl ether phosphate may comprise a monoester phosphate, a diester phosphate, or two or more of these. In some embodiments, the polyoxyethylene alkyl ether phosphate has the following structure: [(alkyl chain)-(polyethylene oxide)-O]ₘ-phosphoric acid, wherein m is 1 or 2 or 3.

In some embodiments, the surfactant has, in the structure of the compound, at least one of an arylene structure and “—CH═CH—”. In some embodiments, the number of “—CH═CH—” in the structure of the compound may be one, two, three, or four.

In some embodiments, the surfactant has a structure represented by the following formula (I):

[tail-Aₙ-O]ₘ—PO_{q}Hᵣ (I)
wherein A is oxyalkylene, the alkylene has 1, 2, or 3 carbon atoms, n is 1, 2, 3, 4, 5, 6, 7, 8, 9, 10, 11, 12, 13, 14, 15, 16, 17, 18, 19, or 20. In some embodiments, n (e.g., the number of EO groups) is less than 10. In some embodiments, m is 1, 2, or 3. In some embodiments, q is 3, 2, or 1. In some embodiments, r is 0, 1, or 2. In some embodiments, n is 1 to 20, 2 to 19, 3 to 18, 4 to 17, 5 to 16, 6 to 15, 5 to 14, 6 to 13, or 8 to 11.

In some embodiments, (m, q, r) is (1, 3, 2), (2, 2, 1), or (3, 1, 0). In some embodiments, n is independently in each instance selected from the group of 1, 2, 3, 4, 5, 6, 7, 8, 9, 10, 11, 12, 13, 14, 15, 16, 17, 18, 19, and 20. In some embodiments, (m, q, r) is (1, 3, 2). In some embodiments, (m, q, r) is (2, 2, 1). In some embodiments, (m, q, r) is (3, 1, 0). In some embodiments, and (m, q, r) is a mixture of (1, 3, 2), (2, 2, 1), and (3, 1, 0).

In some embodiments, the tail comprises a substituted (e.g., phenyl) or unsubstituted straight chain or branched alkyl, alkenyl, alkynyl, phenyl, or alkylaryl. In some embodiments, the alkyl tail comprises a phenyl group (styrenated phenyl or nonyl phenyl). In some embodiments, the numbers of carbon atoms in an alkyl of the alkyl, alkenyl, alkynyl, and alkylaryl are independently 2 to 24, 3 to 23, 4 to 22, 5 to 21, 6 to 20, 6 to 19, 6 to 18, 6 to 17, 6 to 16, 6 to 15, 6 to 14, 6 to 13, 6 to 12, 7 to 19, 8 to 19, 9 to 19, 10 to 23, 11 to 22, 12 to 21, 13 to 20, 14 to 21, or 16 to 20.

In some embodiments, an alkyl disclosed herein may be methyl, ethyl, propyl, isopropyl, butyl, isobutyl, sec-butyl, tert-butyl, pentyl, isopentyl, tert-pentyl, neopentyl, hexyl, isohexyl, heptyl, octyl, nonyl, decyl, undecyl, dodecyl, 2-ethylhexyl, tridecyl, tetradecyl, pentadecyl, hexadecyl, heptadecyl, octadecyl, nonadecyl, eicosyl, henicosyl, or docosyl.

In some embodiments, an alkenyl disclosed herein has a structure of “—CH═CH—” in the structure of the alkenyl (excluding methyl) disclosed above. For example, when the structure of octadecyl has “—CH═CH—”, the octadecyl can become oleyl.

In some embodiments, the aryl is phenyl, napththyl, anthracenyl, or phenanthrenyl. The number of carbon atoms of the alkyl, and the alkyl in the alkylaryl may be 1.

In some embodiments, the tail comprises a hydrocarbon with at least 2, at least 3, at least 4, at least 5, at least 6, at least 7, at least 8, at least 9, at least 10, at least 11, at least 12, at least 13, at least 14, at least 15, at least 16, at least 17, at least 18, at least 19, at least 20, at least 21, at least 22, at least 23, at least 24, or greater number of carbon atoms.

In some embodiments, the tail is alkylaryl, or alkenyl. The numbers of carbon atoms in alkyls in the alkynyl and alkylaryl are independently 2 to 24, 3 to 23, 4 to 22, 5 to 21, 6 to 20, 6 to 19, 6 to 18, 6 to 17, 6 to 16, 6 to 15, 6 to 14, 6 to 13, 6 to 12, 7 to 19, 8 to 19, 9 to 19, 10 to 23, 11 to 22, 12 to 21, 13 to 20, 14 to 21, or 16 to 20. The number of carbon atoms of an alkyl in the alkylaryl may be 1.

In some embodiments, the surfactant (particularly, the phosphate surfactant) has a molecular weight of greater than or equal to about 150 g/mol, greater than or equal to about 200 g/mol, greater than or equal to about 250 g/mol, greater than or equal to about 300 g/mol, greater than or equal to about 350 g/mol, greater than or equal to about 400 g/mol, greater than or equal to about 450 g/mol, greater than or equal to about 500 g/mol, greater than or equal to about 550 g/mol, greater than or equal to about 600 g/mol, greater than or equal to about 650 g/mol, greater than or equal to about 700 g/mol, greater than or equal to about 750 g/mol, greater than or equal to about 800 g/mol, greater than or equal to about 850 g/mol, greater than or equal to about 900 g/mol, greater than or equal to about 950 g/mol, greater than or equal to about 1000 g/mol, greater than or equal to about 1100 g/mol, greater than or equal to about 1200 g/mol, greater than or equal to about 1300 g/mol, greater than or equal to about 1400 g/mol, greater than or equal to about 1500 g/mol, or any range or value therein between.

In some embodiments, the surfactant (particularly, the phosphate surfactant) comprises at least one of laureth-4 phosphate (e.g., Ethfac 142W), polyoxyethylene nonyl phenyl phosphate (e.g., Ethfac NP-110), polyoxyethylene (10) oleyl ether phosphate (e.g., Crodafos O10A), and combinations thereof. In some embodiments, the phosphate surfactant comprises polyoxyethylene nonyl phenyl phosphate (e.g., Ethfac NP-110). In some embodiments, the phosphate surfactant comprises polyoxyethylene (10) oleyl ether phosphate (e.g., Crodafos O10A). Here, (10) means an average number of moles added, and corresponds to “n” in formula (I).

In some embodiments, the surfactant (particularly, the surfactant having at least one of an allylene structure and —CH═CH—, e.g., the surfactant of formula (I)) is present in the polishing composition at a concentration by weight, relative to the total weight of the composition, of about 0.01 wt. % to about 1 wt. %, about 0.05 wt. % to about 1 wt. %, about 0.1 wt. % to about 1 wt. %, about 0.05 wt. % to about 0.1 wt. %, or about 0.05 wt. % to about 0.5 wt. %. In some embodiments, the surfactant (particularly, the surfactant having at least one of an allylene structure and —CH═CH—, e.g., the surfactant of formula (I)) is present in the polishing composition at a concentration by weight, relative to the total weight of the composition, of about 0.001 wt. % to about 10 wt. %, about 0.005 wt. % to about 5.0 wt. %, about 0.008 wt. % to about 4.0 wt. %, about 0.01 wt. % to about 3.0 wt. %, about 0.02 wt. % to about 2.0 wt. %, about 0.03 wt. % to about 1.0 wt. %, about 0.04 wt. % to about 0.8 wt. %, about 0.05 wt. % to about 0.7 wt. %, about 0.06 wt. % to about 0.6 wt. %, or about 0.07 wt. % to about 0.5 wt. %. In some embodiments, the surfactant (particularly, the surfactant having at least one of an allylene structure and —CH═CH—, e.g., the surfactant of formula (I)) is present in the polishing composition at a concentration of 0.01 wt. % to 0.3 wt. %.

In some embodiments, the surfactant (particularly, the surfactant having at least one of an allylene structure and —CH═CH—, e.g., the surfactant of formula (I)) is present in the polishing composition at a concentration by weight, relative to the total weight of the polishing composition, of greater than or equal to about 0.001 wt. %, greater than or equal to about 0.01 wt. %, greater than or equal to about 0.02 wt. %, greater than or equal to about 0.03 wt. %, greater than or equal to about 0.04 wt. %, greater than or equal to about 0.05 wt. %, greater than or equal to about 0.06 wt. %, greater than or equal to about 0.07 wt. %, greater than or equal to about 0.08 wt. %, greater than or equal to about 0.09 wt. %, greater than or equal to about 0.1 wt. %, greater than or equal to about 0.2 wt. %, greater than or equal to about 0.3 wt. %, greater than or equal to about 0.4 wt. %, greater than or equal to about 0.5 wt. %, greater than or equal to about 0.6 wt. %, greater than or equal to about 0.7 wt. %, greater than or equal to about 0.8 wt. %, greater than or equal to about 0.9 wt. %, greater than or equal to about 1.0 wt. %, or any range or value therein between. In some embodiments, the surfactant (particularly, the surfactant having at least one of an allylene structure and —CH═CH—, e.g., the surfactant of formula (I)) is present in the polishing composition at a concentration of less than or equal to about 10 wt. %, less than or equal to about 9.0 wt. %, less than or equal to about 8.0 wt. %, less than or equal to about 7.0 wt. %, less than or equal to about 6.0 wt. %, less than or equal to about 5.0 wt. %, less than or equal to about 4.0 wt. %, less than or equal to about 3.0 wt. %, less than or equal to about 2.0 wt. %, less than or equal to about 1.0 wt. %, less than or equal to about 0.8 wt. %, less than or equal to about 0.7 wt. %, less than or equal to about 0.6 wt. %, or less than or equal to about 0.5 wt. %.

### Additional Surfactants

In some embodiments, polishing compositions according to the present disclosure may comprise one or more surfactants according to the following formula (II):

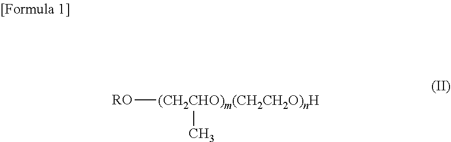

wherein m is % propylene oxide (PO) by weight, and is 20% to 60% by weight of the total PO and EO units, n is % ethylene oxide (EO) by weight, and is 40% to 80% by weight of the total PO and EO units, R is a C₂₋₇ alkyl, and a weight ratio of EO to PO (EO:PO) is 2:3 to 4:1. In some embodiments, R is a C₂₋₆ alkyl, or a C₃₋₅ alkyl.

In some embodiments, m is about 20%, 25%, 30%, 35%, 40%, 45%, 50%, 55%, or 60% by weight (or ranges thereinbetween) of the total PO and EO units in the surfactant of formula (II). In some embodiments, the number of EO units in the surfactant is about 1, 2, 3, 4, 5, 6, 7, 8 9, 10, 12, 15, 18, 20, 22, 25, 28, 30, 32, 35, 38, 40, 42, 45, 48, or 50. In some embodiments, n is about 40%, 45%, 50%, 55%, 60%, 65%, 70%, 75%, or 80% by weight (or ranges thereinbetween) of the total PO and EO units in the surfactant of formula (II). In some embodiments, the number of PO units in the surfactant is about 1, 2, 3, 4, 5, 6, 7, 8 9, 10, 12, 15, 18, 20, 22, 25, 28, 30, 32, 35, 38, 40, 42, 45, 48, or 50. In some embodiments, the weight ratio of EO to PO (EO:PO) is 2:3, 1:1, 4:3, 5:3, 2:1, 7:3, 8:3, 3:1, 10:3, 11:3, or 4:1, or ranges thereinbetween. In some embodiments, R is a C₂, C₃, C₄, C₅, C₆, or C₇ alkyl, which may be branched or linear, and may be optionally substituted. In some embodiments, the surfactant of formula (II) can comprise a polyalkylene glycol monoalkyl ether, and for example, comprises a polyalkylene glycol monobutyl ether (e.g., UCON-50-400, UCON-50-2000, or any of the similar compounds disclosed in U.S. Pat. No. 11,001,733, which is hereby incorporated by reference in its entirety). In some embodiments, the number of carbon atoms of an alkyl of the polyalkylene glycol monoalkyl ether can be 1 to 8, 2 to 7, 3 to 6, 4, or 5.

In some embodiments, the surfactant of formula (II) has a molecular weight of greater than or equal to about 1000 g/mol, greater than or equal to about 1100 g/mol, greater than or equal to about 1200 g/mol, greater than or equal to about 1300 g/mol, greater than or equal to about 1400 g/mol, greater than or equal to about 1500 g/mol, greater than or equal to about 1600 g/mol, greater than or equal to about 1700 g/mol, greater than or equal to about 1800 g/mol, greater than or equal to about 1900 g/mol, greater than or equal to about 2000 g/mol, greater than or equal to about 2100 g/mol, greater than or equal to about 2200 g/mol, greater than or equal to about 2300 g/mol, greater than or equal to about 2400 g/mol, greater than or equal to about 2500 g/mol, greater than or equal to about 2600 g/mol, greater than or equal to about 2700 g/mol, greater than or equal to about 2800 g/mol, greater than or equal to about 2900 g/mol, greater than or equal to about 3000 g/mol, greater than or equal to about 3500 g/mol, greater than or equal to about 4000 g/mol, greater than or equal to about 4500 g/mol, greater than or equal to about 5000 g/mol, greater than or equal to about 5500 g/mol, greater than or equal to about 6000 g/mol, greater than or equal to about 6500 g/mol, or greater than or equal to about 7000 g/mol, or any range or value therein between. In some embodiments, the surfactant of formula (II) has a molecular weight of greater than about 1000 g/mol, 1100 g/mol, about 1200 g/mol, about 1300 g/mol, about 1400 g/mol, about 1500 g/mol, about 1600 g/mol, about 1700 g/mol, about 1800 g/mol, about 1900 g/mol, about 2000 g/mol, about 2100 g/mol, about 2200 g/mol, about 2300 g/mol, about 2400 g/mol, about 2500 g/mol, about 2600 g/mol, about 2700 g/mol, about 2800 g/mol, about 2900 g/mol, about 3000 g/mol, about 3500 g/mol, about 4000 g/mol, about 4500 g/mol, about 5000 g/mol, about 5500 g/mol, about 6000 g/mol, about 6500 g/mol, about or 7000.

In some embodiments, the surfactant of formula (II) is present in the composition at a concentration by weight, relative to the total weight of the polishing composition, of about 0.01 wt. % to about 1 wt. %, about 0.05 wt. % to about 1 wt. %, about 0.1 wt. % to about 1 wt. %, about 0.05 wt. % to about 0.1 wt. %, or 0.05 wt. % to about 0.5 wt. %. In some embodiments, the surfactant of formula (II) is present in the polishing composition at a concentration by weight, relative to the total weight of the composition, of about 0.001 wt. % to about 10 wt. %, about 0.005 wt. % to about 5.0 wt. %, about 0.008 wt. % to about 4.0 wt. %, about 0.01 wt. % to about 3.0 wt. %, about 0.02 wt. % to about 2.0 wt. %, about 0.03 wt. % to about 1.0 wt. %, about 0.04 wt. % to about 0.8 wt. %, about 0.05 wt. % to about 0.7 wt. %, about 0.06 wt. % to about 0.6 wt. %, or about 0.07 wt. % to about 0.5 wt. %. In some embodiments, the surfactant of formula (II) is present at a concentration by weight, relative to the total weight of the polishing composition, of greater than or equal to about 0.01 wt. %, greater than or equal to about 0.02 wt. %, greater than or equal to about 0.03 wt. %, greater than or equal to about 0.04 wt. %, greater than or equal to about 0.05 wt. %, greater than or equal to about 0.06 wt. %, greater than or equal to about 0.07 wt. %, greater than or equal to about 0.08 wt. %, greater than or equal to about 0.09 wt. %, greater than or equal to about 0.1 wt. %, greater than or equal to about 0.2 wt. %, greater than or equal to about 0.3 wt. %, greater than or equal to about 0.4 wt. %, greater than or equal to about 0.5 wt. %, greater than or equal to about 0.6 wt. %, greater than or equal to about 0.7 wt. %, greater than or equal to about 0.8 wt. %, greater than or equal to about 0.9 wt. %, greater than or equal to about 1.0 wt. %, or any range or value therein between. In some embodiments, the surfactant of formula (II) is present at a concentration by weight, relative to the total weight of the polishing composition, of less than or equal to about 10 wt. %, less than or equal to about 9.0 wt. %, less than or equal to about 8.0 wt. %, less than or equal to about 7.0 wt. %, less than or equal to about 6.0 wt. %, less than or equal to about 5.0 wt. %, less than or equal to about 4.0 wt. %, less than or equal to about 3.0 wt. %, less than or equal to about 2.0 wt. %, less than or equal to about 1.0 wt. %, less than or equal to about 0.8 wt. %, less than or equal to about 0.7 wt. %, less than or equal to about 0.6 wt. %, or less than or equal to about 0.5 wt. %.

### Metal Corrosion Inhibitor

In some embodiments, a polishing composition according to the present disclosure comprises a metal corrosion inhibitor (e.g., a Cu corrosion inhibitor or Co corrosion inhibitor). Without being bound by the theory, it is contemplated that the corrosion inhibitor passivates a metal surface (e.g., Cu or Co surface) to prevent pitting and other types of corrosion defects during CMP. By way of non-limiting example, in some embodiments, the inhibitor may comprise one or more of the following: benzotriazole (BTA), 1,2,4-triazole, tetrazole, tolytriazole, 4-carboxybenzotriazole, 5-carboxybenzotriale, mercaptobenzoxazole, 2-mercaptobenzothiazole, 2-mercaptobenzimidazole, and derivatives thereof. In some embodiments, the inhibitor comprises benzotriazole (BTA).

The concentration of the inhibitor may be any suitable concentration to prevent corrosion, pitting, or etching of, e.g., Cu or Co, at the pH of the polishing composition. In some embodiments, the concentration of the inhibitor is from 0.001 wt. % to 1 wt. %, from 0.01 wt. % to 1 wt. %, from 0.1 wt. % to 1 wt. %, from 0.001 wt. % to 0.1 wt. %, from 0.001 wt. % to 0.01 wt. %, or from 0.01 wt. % to 0.1 wt. %, relative to the total weight of the composition. In some embodiments, the inhibitor is present in the polishing composition at a concentration, relative to the total weight of the polishing composition, of greater than or equal to about 0.001 wt. %, greater than or equal to about 0.002 wt. %, greater than or equal to about 0.003 wt. %, greater than or equal to about 0.004 wt. %, greater than or equal to about 0.005 wt. %, greater than or equal to about 0.006 wt. %, greater than or equal to about 0.007 wt. %, greater than or equal to about 0.008 wt. %, greater than or equal to about 0.009 wt. %, greater than or equal to about 0.01 wt. %, greater than or equal to about 0.02 wt. %, greater than or equal to about 0.03 wt. %, greater than or equal to about 0.04 wt. %, greater than or equal to about 0.05 wt. %, greater than or equal to about 0.06 wt. %, greater than or equal to about 0.07 wt. %, greater than or equal to about 0.08 wt. %, greater than or equal to about 0.09 wt. %, greater than or equal to about 0.1 wt. %, greater than or equal to about 0.2 wt. %, greater than or equal to about 0.3 wt. %, greater than or equal to about 0.4 wt. %, greater than or equal to about 0.5 wt. %, greater than or equal to about 0.6 wt. %, greater than or equal to about 0.7 wt. %, greater than or equal to about 0.8 wt. %, greater than or equal to about 0.9 wt. %, greater than or equal to about 1 wt. %. In some embodiments, the concentration of the inhibitor is less than or equal to 5 wt. %, less than or equal to 1 wt. %, less than or equal to 0.5 wt. %, less than or equal to 0.1 wt. %, or less than or equal to 0.05 wt. %, relative to the total weight of the polishing composition.

### Water-Soluble Polymer

Herein, the term “water-soluble” may mean that solubility in water (25° C.) is greater than or equal to 1 g/100 mL.

In some embodiments, the polishing composition according to the present disclosure comprises one or more water-soluble polymers. The one or more water-soluble polymers is not particularly limited. A non-limiting example of the water-soluble polymers includes one or more saccharides. Examples of the saccharides include starch derivatives and cellulose derivatives. Examples of the starch derivatives include glucans such as pregelatinized starch, cyclodextrin, and pullulan. Examples of the cellulose derivatives include hydroxymethyl cellulose, hydroxyethyl cellulose (HEC), hydroxypropyl cellulose, hydroxyethylmethyl cellulose, hydroxypropylmethyl cellulose, methyl cellulose, ethyl cellulose, ethylhydroxyethyl cellulose, and carboxymethyl cellulose. Other non-limiting examples include one or more imine derivatives such as poly(N-acylalkyleneimine); polyvinyl alcohol (PVA); modified (cation modified or non-ion modified) polyvinyl alcohol; polyvinyl pyrrolidone (PVP); polyvinylcaprolactam; and polyoxyalkylenes (e.g., polyoxyethylene), and copolymers and combinations of these. The one or more water-soluble polymers may be used alone or as a combination of two or more of kinds. In some embodiments, the polishing composition according to the present embodiment comprises a polysaccharide. In some embodiments, the polysaccharide is glucan. In some embodiments, the glucan may be at least one of α-glucan and β-glucan, and is suitably α-glucan. In some embodiments, examples of the α-glucan include amylose, amylopectin, pullulan, and dextran. In some embodiments, examples of the β-glucan include laminaran, curdlan, callose, and cellulose.

In some embodiments, the water-soluble polymer has a molecular weight (mass average molar mass) of greater than or equal to about 500 g/mol, greater than or equal to about 1000 g/mol, greater than or equal to about 1500 g/mol, greater than or equal to about 2000 g/mol, greater than or equal to about 2500 g/mol, greater than or equal to about 3000 g/mol, greater than or equal to about 3500 g/mol, greater than or equal to about 4000 g/mol, greater than or equal to about 4500 g/mol, greater than or equal to about 5000 g/mol, greater than or equal to about 5500 g/mol, greater than or equal to about 6000 g/mol, greater than or equal to about 6500 g/mol, greater than or equal to about 7000 g/mol, greater than or equal to about 7500 g/mol, greater than or equal to about 8000 g/mol, greater than or equal to about 8500 g/mol, greater than or equal to about 9000 g/mol, greater than or equal to about 9500 g/mol, greater than or equal to 10000 g/mol, greater than or equal to about 15000 g/mol, greater than or equal to about 20000 g/mol, greater than or equal to about 25000 g/mol, greater than or equal to about 30000 g/mol, greater than or equal to about 35000 g/mol, greater than or equal to about 40000 g/mol, greater than or equal to about 45000 g/mol, greater than or equal to about 50000 g/mol, greater than or equal to about 55000 g/mol, greater than or equal to about 60000 g/mol, greater than or equal to about 65000 g/mol, greater than or equal to about 70000 g/mol, greater than or equal to about 75000 g/mol, greater than or equal to about 80000 g/mol, greater than or equal to about 85000 g/mol, greater than or equal to about 90000 g/mol, greater than or equal to about 95000 g/mol, greater than or equal to about 100000 g/mol, greater than or equal to about 150000 g/mol, greater than or equal to about 200000 g/mol, greater than or equal to about 250000 g/mol, greater than or equal to about 300000 g/mol, greater than or equal to about 350000 g/mol, greater than or equal to about 400000 g/mol, greater than or equal to about 450000 g/mol, greater than or equal to about 500000 g/mol, or any range or value therein between (e.g., 5,000 to 300,000 g/mol).

In some embodiments, the molecular weight (mass average molar mass) may be measured with a gel permeation chromatography (GPC) apparatus with the water-soluble polymer dissolved in a solvent such as dimethyl acetamide (DMAc) or polystyrene, and with polystyrene used as a reference substance.

In some embodiments, the one or more water-soluble polymers is present at a concentration, by weight, relative to the total weight of the polishing composition, of about 0.001 wt. % to about 5 wt. %, about 0.005 wt. % to about 5 wt. %, about 0.01 wt. % to about 5 wt. %, about 0.05 wt. % to about 5 wt. %, about 0.1 wt. % to about 5 wt. %, about 0.5 wt. % to about 5 wt. %, about 1 wt. % to about 5 wt. %, about 0.001 wt. % to about 1 wt. %, about 0.005 wt. % to about 1 wt. %, about 0.01 wt. % to about 1 wt. %, about 0.05 wt. % to about 1 wt. %, about 0.1 wt. % to about 1 wt. %, about 0.5 wt. % to about 1 wt. %, about 0.001 wt. % to about 0.1 wt. %, about 0.005 wt. % to about 0.1 wt. %, about 0.01 wt. % to about 0.1 wt. %, about 0.05 wt. % to about 0.1 wt. %, about 0.001 wt. % to about 0.1%, or any range or value therein between (e.g. about 0.001 wt. %, about 0.002 wt. %, about 0.003 wt. %, about 0.004 wt. %, about 0.005 wt. %, about 0.006 wt. %, about 0.007 wt. %, about 0.008 wt. %, about 0.009 wt. %, about 0.01 wt. %, about 0.02 wt. %, about 0.03 wt. %, about 0.04 wt. %, about 0.05 wt. %, about 0.06 wt. %, about 0.07 wt. %, about 0.08 wt. %, about 0.09 wt. %, about 0.1 wt. %, about 0.2 wt. %, about 0.3 wt. %, about 0.4 wt. %, about 0.5 wt. %, about 0.6 wt. %, about 0.7 wt. %, about 0.8 wt. %, about 0.9 wt. %, about 1 wt. %, about 2 wt. %, about 3 wt. %, about 4 wt. %, or about 5 wt. %). In some embodiments, the one or more water-soluble polymers is present at a concentration, by weight, relative to the total weight of the polishing composition, of greater than or equal to about 0.001 wt. %, greater than or equal to about 0.003 wt. %, greater than or equal to about 0.005 wt. %, greater than or equal to about 0.007 wt. %, greater than or equal to about 0.009 wt. %, greater than or equal to about 0.011 wt. %, greater than or equal to about 0.013 wt. %, greater than or equal to about 0.015 wt. %, or greater than or equal to about 0.017 wt. %. In some embodiments, the one or more water-soluble polymers is present at a concentration, by weight, relative to the total weight of the polishing composition, of less than or equal to about 5 wt. %, less than or equal to about 4 wt. %, less than or equal to about 3 wt. %, less than or equal to about 2 wt. %, less than or equal to about 1 wt. %, less than or equal to about 0.8 wt. %, less than or equal to about 0.5 wt. %, less than or equal to about 0.3 wt. %, less than or equal to about 0.1 wt. %, less than or equal to about 0.08 wt. %, less than or equal to about 0.06 wt. %, or less than or equal to about 0.05 wt. %.

### Acidic Compound

In some embodiments, the polishing composition according to the present disclosure comprises one or more acidic compounds. In some embodiments, the one or more acidic compounds comprises one or more organic acids (e.g., carboxylic acids including formic acid, acetic acid, propionic acid, butyric acid, valeric acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, glycolic acid, salicylic acid, glyceric acid, oxalic acid, malonic acid, succinic acid, glutaric acid, adipic acid, pimelic acid, maleic acid, phthalic acid, malic acid, tartaric acid, citric acid, and lactic acid; and organic sulfuric acids including methanesulfonic acid, ethanesulfonic acid, and isethionic acid, and any combination thereof). In some embodiments, the acidic compound comprises 2-hydroxy phosphonoacetic acid (HPAA).

In some embodiments, the one or more acidic compounds is present at a concentration, by weight, relative to the total weight of the polishing composition, of about 0.001 wt. % to about 5 wt. %, about 0.005 wt. % to about 5 wt. %, about 0.01 wt. % to about 5 wt. %, about 0.05 wt. % to about 5 wt. %, about 0.1 wt. % to about 5 wt. %, about 0.5 wt. % to about 5 wt. %, about 1 wt. % to about 5 wt. %, about 0.001 wt. % to about 1 wt. %, about 0.005 wt. % to about 1 wt. %, about 0.01 wt. % to about 1 wt. %, about 0.05 wt. % to about 1 wt. %, about 0.1 wt. % to about 1 wt. %, about 0.5 wt. % to about 1 wt. %, about 0.001 wt. % to about 0.1 wt. %, about 0.005 wt. % to about 0.1 wt. %, about 0.01 wt. % to about 0.1 wt. %, about 0.05 wt. % to about 0.1 wt. %, about 0.001 wt. % to about 0.1%, or any range or value therein between (e.g. about 0.001 wt. %, about 0.002 wt. %, about 0.003 wt. %, about 0.004 wt. %, about 0.005 wt. %, about 0.006 wt. %, about 0.007 wt. %, about 0.008 wt. %, about 0.009 wt. %, about 0.01 wt. %, about 0.02 wt. %, about 0.03 wt. %, about 0.04 wt. %, about 0.05 wt. %, about 0.06 wt. %, about 0.07 wt. %, about 0.08 wt. %, about 0.09 wt. %, about 0.1 wt. %, about 0.2 wt. %, about 0.3 wt. %, about 0.4 wt. %, about 0.5 wt. %, about 0.6 wt. %, about 0.7 wt. %, about 0.8 wt. %, about 0.9 wt. %, about 1 wt. %, about 2 wt. %, about 3 wt. %, about 4 wt. %, or about 5 wt. %).

### pH Adjusting Agent

In some embodiments, a composition according to the present disclosure may further comprise one or more pH adjusting agents to adjust the pH to a selected pH value.

The pH adjusting agent is not particularly limited, and any suitable pH adjusting agent may be used to bring the pH of the composition into any desired range, as discussed above. In some embodiments, the one or more pH adjusting agents may comprise, consist essentially of, or consist of an inorganic compound, an organic compound, or combinations thereof. In some embodiments, the one or more pH adjusting agents may comprise inorganic acids (e.g., hydrochloric acid, hydrobromic acid, hydroiodic acid, sulfuric acid, nitric acid, boric acid, carbonic acid, hypophosphorous acid, phosphorous acid, and phosphoric acid); organic acids (e.g., carboxylic acids such as citric acid, formic acid, acetic acid, propionic acid, benzoic acid, salicylic acid, glyceric acid, oxalic acid, malonic acid, succinic acid, maleic acid, phthalic acid, malic acid, tartaric acid, and lactic acid); and/or organic sulfuric acids (e.g., methane sulfonic acid, ethane sulfonic acid, isethionic acid, etc.). In some embodiments, the one or more pH adjusting agents may comprise a divalent or higher acid of the above acid(s) (e.g., sulfuric acid, carbonic acid, phosphoric acid, oxalic acid, etc.), which may be in the form of a base when one or more protons (H⁺) can be released (e.g., ammonium hydrogen carbonate or ammonium hydrogen phosphate), but any counter-ion may be used (e.g., weakly basic cations, such as ammonium, triethanolamine, etc.). In some embodiments, the one or more pH adjusting agents comprises nitric acid.

In some embodiments, the composition according to the present disclosure comprises an organic acid having one or more hydroxy groups and two or more carboxyl groups. Such an organic acid can be a pH adjusting agent used for adjusting the pH. The number of hydroxy groups can be 1, 2, 3, 4, 5 or 6. The number of carboxyl groups can be 1, 2, 3, 4, 5, or 6. In some embodiments, the organic acid comprises acetic acid, lactic acid, oxalic acid, malonic acid, tartaric acid, malic acid, valeric acid, citric acid, aconitic acid, succinic acid, glycolic acid, salicylic acid, glyceric acid, glutaric acid, adipic acid, pimelic acid, maleic acid, phthalic acid, hydroxycaprylic acid, hydroxycapric acid, polyacrylic acid, and a combination thereof.

In some embodiments, the one or more pH adjusting agents may comprise one or more hydroxides of alkali metals (e.g., NaOH, KOH), or salts thereof (e.g., carbonates, hydrogen carbonates, sulfates, acetates, etc.); quaternary ammonium compounds (e.g., tetramethylammonium, tetraethylammonium, tetrabutylammonium, etc.); quaternary ammonium hydroxides (e.g., tetramethylammonium hydroxide, tetraethylammonium hydroxide, tetrabutylammonium hydroxide) or a salts thereof; ammonia; amines; or any other suitable pH adjusting agent.

### pH of Polishing Composition

The pH adjust agent may be present in any amount suitable to achieve a desired pH value, as discussed above. In some embodiments, the pH of the composition is basic (e.g., greater than 7). In some embodiments, the pH of the composition is greater than 7, greater than or equal to 7.1, greater than or equal to 7.2, greater than or equal to 7.3, greater than or equal to 7.4, greater than or equal to 7.5, greater than or equal to 7.6, greater than or equal to 7.7, greater than or equal to 7.8, greater than or equal to 7.9, greater than or equal to 8.0, greater than or equal to 8.1, greater than or equal to 8.2, greater than or equal to 8.3, greater than or equal to 8.4, greater than or equal to 8.5, greater than or equal to 8.6, greater than or equal to 8.7, greater than or equal to 8.8, greater than or equal to 8.9, greater than or equal to 9.0, greater than or equal to 9.1, greater than or equal to 9.2, greater than or equal to 9.3, greater than or equal to 9.4, greater than or equal to 9.5, greater than or equal to 9.6, greater than or equal to 9.7, greater than or equal to 9.8, greater than or equal to 9.9, greater than or equal to 10.0, or any range or value therein between.

In some embodiments, the pH of the composition is less than or equal to about 10.0, less than or equal to about 9.9, less than or equal to about 9.8, less than or equal to about 9.7, less than or equal to about 9.6, less than or equal to about 9.5, less than or equal to about 9.4, less than or equal to about 9.3, less than or equal to about 9.2, less than or equal to about 9.1, less than or equal to about 9.0, less than or equal to about 8.9, less than or equal to about 8.8, less than or equal to about 8.7, less than or equal to about 8.6, less than or equal to about 8.5, less than or equal to about 8.4, less than or equal to about 8.3, less than or equal to about 8.2, less than or equal to about 8.1, less than or equal to about 8.0, less than or equal to about 7.9, less than or equal to about 7.8, less than or equal to about 7.7, less than or equal to about 7.6, less than or equal to about 7.5, or any range or value therein between.

In some embodiments, the pH of the composition is 7 to 10, 7.1 to 10.0, 7.2 to 10.0, 7.4 to 10.0, 7.6 to 10.0, 7.8 to 10.0, 8.0 to 10.0, 8.1 to 10.0, 8.2 to 10.0, 8.6 to 10.0, 8.8 to 10.0, 9.0 to 10.0, or any range or value therein between. In some embodiment, the pH of the composition is greater than 7 and less than or equal to 10, 7.2 to 9.9, 7.4 to 9.9, 7.6 to 9.8, 7.8 to 9.8, 8.0 to 9.8, 8.0 to 9.8, 8.2 to 9.7, 8.4 to 9.7, 8.6 to 9.7, 8.8 to 9.7, 9.0 to 9.6, 9.2 to 9.6, or any range or value therein between. In some embodiments, the pH of the composition is about 7, about 7.5, about 8, about 8.5, about 9, about 9.5, about 10, or any range or value therein between.

In some embodiments, the one or more pH adjusting agents are present in the composition at a concentration, relative to the total weight of the composition, of greater than or equal to about 0.1 wt. %, greater than or equal to about 0.15 wt. %, greater than or equal to about 0.2 wt. %, greater than or equal to about 0.25 wt. %, greater than or equal to about 0.3 wt. %, greater than or equal to about 0.35 wt. %, greater than or equal to about 0.4 wt. %, greater than or equal to about 0.45 wt. %, greater than or equal to about 0.5 wt. %, greater than or equal to about 0.55 wt. %, greater than or equal to about 0.60 wt. %, greater than or equal to about 0.65 wt. %, greater than or equal to about 0.7 wt. %, or any range or value therein between. In some embodiments, the one or more pH adjusting agents are present in the composition at a concentration, relative to the total weight of the composition, of less than or equal to about 10.0 wt. %, less than or equal to about 9.0 wt. %, less than or equal to about 8.0 wt. %, less than or equal to about 7.0 wt. %, less than or equal to about 6.0 wt. %, less than or equal to about 5.0 wt. %, less than or equal to about 4.0 wt. %, less than or equal to about 3.0 wt. %, less than or equal to about 2.0 wt. %, less than or equal to about 1.5 wt. %, or any range or value therein between.

In some embodiment, the concentration of the one or more pH adjusting agents in the composition is a sufficient amount for adjusting to a desired pH.

### Oxidizers

In some embodiments, the polishing compositions of the present disclosure may comprise at least one oxidizer. An oxidizer may be added to the present polishing composition to oxidize a metal surface (e.g., Cu) of a polishing object, thereby enhancing the metal removal rate of the polishing process. In some embodiments, an oxidizer is added to the polishing composition only immediately prior to use. In other embodiments, an oxidizer is mixed with other ingredients of the polishing composition at approximately the same time during a manufacturing procedure. In some embodiments, the present composition is manufactured and sold as a stock composition, and an end customer can choose to dilute the stock composition as needed and/or add a suitable amount of an oxidizer before using.

In some embodiments, non-limiting examples of the oxidizer which may be used include, but are not limited to, a peroxide, hydrogen peroxide, sodium peroxide, barium peroxide, an organic oxidizer, ozone water, a silver (II) salt, an iron (III) salt, permanganese acid, chromic acid, dichromic acid, peroxodisulfuric acid, peroxophosphoric acid, peroxosulfuric acid, peroxoboric acid, performic acid, peracetic acid, perbenzoic acid, perphthalic acid, hypochlorous acid, hypobromous acid, hypoiodous acid, chloric acid, chlorous acid, perchloric acid, bromic acid, iodic acid, periodic acid, persulfuric acid, dichloroisocyanuric acid, and a salt thereof. The oxidizer may be used either singly or as a mixture of two or more kinds. In some embodiments, the oxidizer comprises, hydrogen peroxide, ammonium persulfate, periodic acid, hypochlorous acid, sodium dichloroisocyanurate, or mixtures thereof. In some embodiment, the oxidizer comprises hydrogen peroxide (e.g., 30 mass % H₂O₂).

In some embodiments, the one or more oxidizers are present in the composition at a concentration, in terms of an effective concentration, relative to the total weight of the composition, of greater than or equal to about 0.1 wt. %, greater than or equal to about 0.15 wt. %, greater than or equal to about 0.2 wt. %, greater than or equal to about 0.25 wt. %, greater than or equal to about 0.3 wt. %, greater than or equal to about 0.35 wt. %, greater than or equal to about 0.4 wt. %, greater than or equal to about 0.45 wt. %, greater than or equal to about 0.5 wt. %, greater than or equal to about 0.55 wt. %, greater than or equal to about 0.60 wt. %, greater than or equal to about 0.65 wt. %, greater than or equal to about 0.7 wt. %, greater than or equal to about 0.75 wt. %, greater than or equal to about 0.8 wt. %, greater than or equal to about 0.85 wt. %, greater than or equal to about 0.9 wt. %, greater than or equal to about 0.95 wt. %, greater than or equal to about 1.0 wt. %, greater than or equal to about 1.1 wt. %, greater than or equal to about 1.2 wt. %, greater than or equal to about 1.3 wt. %, greater than or equal to about 1.4 wt. %, greater than or equal to about 1.5 wt. %, greater than or equal to about 1.6 wt. %, greater than or equal to about 1.7 wt. %, greater than or equal to about 1.8 wt. %, greater than or equal to about 1.9 wt. %, greater than or equal to about 2.0 wt. %, greater than or equal to about 2.5 wt. %, greater than or equal to about 3.0 wt. %, greater than or equal to about 3.5 wt. %, greater than or equal to about 4.0 wt. %, greater than or equal to about 4.5 wt. %, greater than or equal to about 5.0 wt. %, greater than or equal to about 5.5 wt. %, greater than or equal to about 6.0 wt. %, greater than or equal to about 6.5 wt. %, greater than or equal to about 7.0 wt. %, greater than or equal to about 7.5 wt. %, greater than or equal to about 8.0 wt. %, greater than or equal to about 8.5 wt. %, greater than or equal to about 9.0 wt. %, greater than or equal to about 9.5 wt. %, greater than or equal to about 10.0 wt. %, or any range or value therein between. In some embodiments, the one or more oxidizers are present in the composition at a concentration, in terms of an effective concentration, relative to the total weight of the composition, of less than or equal to about 10.0 wt. %, less than or equal to about 9.0 wt. %, less than or equal to about 8.0 wt. %, less than or equal to about 7.0 wt. %, less than or equal to about 6.0 wt. %, less than or equal to about 5.0 wt. %, less than or equal to about 4.0 wt. %, greater than or equal to about 3.0 wt. %, less than or equal to about 2.0 wt. %, or any range or value therein between.

As the content of the one or more oxidizers decreases, the cost involved with materials of the polishing composition can be saved and a load involved with waste treatment after use of the polishing composition can be reduced. It is also possible to reduce the possibility of excessive oxidation of a surface by reducing the content of an oxidizer.

### Salts

In some embodiments, a polishing composition according to the present disclosure further comprises a salt. The salt may be any salt that is suitable for polishing compositions (e.g., for adjusting ionic strength of the composition). For example, in some embodiments, the salt is a citrate salt, such as potassium citrate, e.g., tripotassium citrate. In some embodiments, the salt is a nitrate salt, such as sodium nitrate, potassium nitrate, ammonium nitrate. In some embodiments, the salt is an acetate salt, such as sodium acetate, potassium acetate, ammonium acetate. In some embodiments, the salt is a halide salt (e.g., NaCl or KCl). In some embodiments, the salt may comprise KHCO₃ or NaHCO₃. The salt may also be in the hydrate form prior to addition.

In some embodiments, the one or more salts is present at a concentration, by weight, relative to the total weight of the polishing composition, of about 0.001 wt. % to about 5 wt. %, about 0.005 wt. % to about 5 wt. %, about 0.01 wt. % to about 5 wt. %, about 0.05 wt. % to about 5 wt. %, about 0.1 wt. % to about 5 wt. %, about 0.5 wt. % to about 5 wt. %, about 1 wt. % to about 5 wt. %, about 0.001 wt. % to about 1 wt. %, about 0.005 wt. % to about 1 wt. %, about 0.01 wt. % to about 1 wt. %, about 0.05 wt. % to about 1 wt. %, about 0.1 wt. % to about 1 wt. %, about 0.5 wt. % to about 1 wt. %, about 0.001 wt. % to about 0.1 wt. %, about 0.005 wt. % to about 0.1 wt. %, about 0.01 wt. % to about 0.1 wt. %, about 0.05 wt. % to about 0.1 wt. %, about 0.001 wt. % to about 0.1%, or any range or value therein between (e.g. about 0.001 wt. %, about 0.002 wt. %, about 0.003 wt. %, about 0.004 wt. %, about 0.005 wt. %, about 0.006 wt. %, about 0.007 wt. %, about 0.008 wt. %, about 0.009 wt. %, about 0.01 wt. %, about 0.02 wt. %, about 0.03 wt. %, about 0.04 wt. %, about 0.05 wt. %, about 0.06 wt. %, about 0.07 wt. %, about 0.08 wt. %, about 0.09 wt. %, about 0.1 wt. %, about 0.2 wt. %, about 0.3 wt. %, about 0.4 wt. %, about 0.5 wt. %, about 0.6 wt. %, about 0.7 wt. %, about 0.8 wt. %, about 0.9 wt. %, about 1 wt. %, about 2 wt. %, about 3 wt. %, about 4 wt. %, or about 5 wt. %).

### Other Additives

In some embodiments, the composition may comprise other additives at any concentration. However, it is desirable not to add unnecessary components, which may cause the presence of surface defects. Thus, it is preferred that any other additives are present in relatively small concentrations (e.g., 0.1 wt. % or less, 0.05 wt. % or less, 0.01 wt. % or less, 0.005 wt. % or less, 0.001 wt. % or less, 0.0005 wt. % or less, 0.0001 wt. % or less, 0.0001 wt. % to 0.1 wt. %, 0.0001 wt. % to 0.01 wt. %, or 0.0001 wt. % to 0.001 wt. %, etc.) if they are present at all. Examples of other additives include antiseptic agents, biocides (e.g., isothiazolinones such as methylisothiazolinone (“MIT”), benzisothiazolinone (“BIT”), etc.), dissolved gases, wetting controllers (“wetting agents,” e.g., hydroxyethylcellulose, N,N-dimethyldodecylamineoxide, polyvinyl alcohol (PVA), polyvinylpyrrolidone (PVP), poly(N-vinylacetamide) (PNVA), polypropylene glycol (PPG), polyethylene glycol (PEG), PEG-PPG copolymers or block copolymers (e.g., PEG-PPG, PEG-PPG-PEG, PPG-PEG-PPG, etc.), and combinations thereof), and the like.

### Liquid Carrier

Polishing compositions according to the present disclosure comprise a liquid carrier. The liquid carrier of the polishing composition is not particularly limited. In some embodiments, the liquid carrier is water, such as deionized water. The liquid carrier may also be an aqueous solution that has, e.g., an appropriate pH modifier contained therein. In some embodiments, the liquid carrier can comprise one or more organic solvents, such as an alcohol compound, e.g., glycol ethers of aliphatic alcohols and 3 to 10 carbon atoms having 2 to 6 carbon atoms. Examples of aliphatic alcohols with 2 to 6 carbon atoms include ethanol, 1-propanol, 2-propanol, 1-butanol, 2-butanol, tert-butanol, pentanol, hexanol, ethylene glycol, propylene glycol, 1,3-butanediol, 1,4-butanediol, 1,5-pentanediol, 1,6-hexanediol, glycerin, 1,2,4-butanetriol, 1,2,6-hexanetriol, erythritol, D-threitol, L-threilol, D-arabinitol, L-arabinitol, ribitol, xylitol, mannitol, and sorbitol. Examples of glycol ethers with 3 to 10 carbon atoms include methyl glycol, methyl diglycol, methyl triglycol, isopropyl glycol, isopropyl diglycol, butyl glycol, butyl diglycol, butyl triglycol, isobutyl glycol, isobutyl diglycol, hexyl glycol, hexyl diglycol, 2-ethylhexyl glycol, 2-ethylhexyl diglycol, aryl glycol, phenyl glycol, phenyl diglycol, benzyl glycol, methylpropylene glycol, methylpropylene diglycol, methylpropylene triglycol, propylpropylene glycol, propylpropylene diglycol, butylpropylene glycol, butylpropylene diglycol, and phenylpropylene glycol.

In some embodiment, the polishing composition comprises water as a liquid carrier. Examples of the liquid carrier include water; alcohols including methanol, ethanol, and ethylene glycol; ketones including acetone, and combinations of these. Among these, water is preferred as the liquid carrier. In other words, in a preferable embodiment of the present invention, the liquid carrier comprises water. In a more preferable embodiment of the present invention, the liquid carrier substantially comprises water. This term “substantially” is used to intend that a liquid carrier other than water may be comprised as long as the objective effect of the present invention can be achieved, and more specifically, greater than or equal to 90 mass % and less than or equal to 100 mass % of water, and greater than or equal to 0 mass.% and less than and equal to 10 mass % of a liquid carrier other than water are preferably consisted of, and greater than or equal to 99 mass % and less than or equal to 100 mass % of water, and greater than or equal to 0 mass % and less than or equal to 1 mass % of a liquid carrier other than water are more preferably consisted of. Most preferably, the liquid carrier is water.

In some embodiments, the polishing composition is used for polishing a polishing object, and the polishing object may comprise at least one of cobalt and copper, and tantalum.

Some embodiments provide a polishing composition comprising abrasive grains comprising surface-modified anionic silica particles; and a surfactant, wherein the surfactant is a compound represented by the following formula (I):

[tail-Aₙ-O]ₘ—PO_{q}Hᵣ (I)
wherein the tail is alkenyl or alkylaryl, the alkenyl has 2 to 24 carbon atoms, alkyl of the alkylaryl has 1 to 24 carbon atoms, A is oxyalkylene, the alkylene has 1, 2, or 3 carbon atoms, n is 1 to 20, and m, q, and r are respectively 1, 3, 2; 2, 2, 1; or 3, 1, 0, and
the polishing composition comprises a saccharide, and an organic acid having one or more hydroxy groups and two or more carboxyl groups, and has a pH of 7 to 10.

### Polishing Methods

In another aspect, the present disclosure relates to a method of polishing a substrate surface, wherein the substrate surface comprises cobalt and at least one of tantalum or copper, the method comprising: polishing the substrate surface by applying the polishing composition of any of the above-discussed embodiments to the substrate surface using a polishing pad; wherein the polishing achieves a copper/cobalt polishing rate ratio of between about 0.3 to about 5.

In some embodiments, the polishing compositions according to the present disclosure, or the polishing methods according to the present disclosure achieve a Ta/Co selectivity (RR_{Ta}/RR_{Co}), which is the ratio of the tantalum (Ta) removal rate (Å/min) to the cobalt (Co) removal rate (Å/min), of at least about 6, at least about 7, at least about 8, at least about 9, at least about 10, at least about 11, at least about 12, at least about 13, at least about 14, at least about 15, at least about 20, at least about 25, or any range or value therein between. In some embodiments, the Ta/Co selectivity is at least about 10.

In some embodiments, the polishing compositions according to the present disclosure, or the polishing methods according to the present disclosure achieve a Ta/Co selectivity (RR_{Ta}/RR_{Co}), which is the ratio of the tantalum (Ta) removal rate (Å/min) to the cobalt (Co) removal rate (Å/min), of about 0.3 to about 3, about 0.5 to about 2.5, about 0.8 to about 1.3, about 0.8 to about 1.2, about 0.9 to about 1.1, or about 1. In some embodiments, the Cu/Co selectivity is about 0.5, about 0.6, about 0.7, about 0.8, about 0.9, about 1.0, about 1.1, about 1.2, about 1.3, about 1.4, about 1.5, about 1.6, about 1.7, about 1.8, about 1.9, about 2.0, about 2.1, about 2.2, about 2.3, about 2.4, about 2.5, about 2.6, about 2.7, about 2.8, about 2.9, about, or about 3.0, or any range or value therein between.

In some embodiments, a ratio of the copper polishing rate (Å/min) to the cobalt polishing rate (Å/min) is designed to be the ratio disclosed above, and a ratio of the tantalum polishing rate (Å/min) to the cobalt polishing rate (Å/min) is designed to be the ratio (polishing rate ratio) disclosed above.

In some embodiments, the polishing compositions according to the present disclosure, or the polishing achieve a Co removal rate of greater than or equal to about 1 Å/min, greater than or equal to about 2 Å/min, greater than or equal to about 3 Å/min, greater than or equal to about 4 Å/min, greater than or equal to about 5 Å/min, greater than or equal to about 6 Å/min, greater than or equal to about 7 Å/min, greater than or equal to about 8 Å/min, greater than or equal to about 9 Å/min, greater than or equal to about 10 Å/min, greater than or equal to about 11 Å/min, greater than or equal to about 12 Å/min, greater than or equal to about 13 Å/min, greater than or equal to about 14 Å/min, greater than or equal to about 15 Å/min, greater than or equal to about 16 Å/min, greater than or equal to about 17 Å/min, greater than or equal to about 18 Å/min, greater than or equal to about 19 Å/min, greater than or equal to about 20 Å/min, greater than or equal to about 25 Å/min, greater than or equal to about 30 Å/min, greater than or equal to about 30 Å/min, greater than or equal to about 35 Å/min, greater than or equal to about 40 Å/min, greater than or equal to about 45 Å/min, or greater than or equal to about 50 Å/min, or any range or value therein between.

In some embodiments, the polishing compositions according to the present disclosure, or the polishing achieve a Ta removal rate of greater than or equal to about 50 Å/min, greater than or equal to about 60 Å/min, greater than or equal to about 70 Å/min, greater than or equal to about 80 Å/min, greater than or equal to about 90 Å/min, greater than or equal to about 100 Å/min, greater than or equal to about 110 Å/min, greater than or equal to about 120 Å/min, greater than or equal to about 130 Å/min, greater than or equal to about 140 Å/min, greater than or equal to about 150 Å/min, greater than or equal to about 160 Å/min, greater than or equal to about 170 Å/min, greater than or equal to about 180 Å/min, greater than or equal to about 190 Å/min, greater than or equal to about 200 Å/min, greater than or equal to about 210 Å/min, greater than or equal to about 220 Å/min, greater than or equal to about 230 Å/min, greater than or equal to about 240 Å/min, greater than or equal to about 250 Å/min, greater than or equal to about 260 Å/min, greater than or equal to about 270 Å/min, greater than or equal to about 280 Å/min, greater than or equal to about 290 Å/min, or greater than or equal to about 300 Å/min, or any range or value therein between.

In some embodiments, the polishing compositions according to the present disclosure, or the polishing achieve a Cu removal rate of greater than or equal to about 5 Å/min, greater than or equal to about 10 Å/min, greater than or equal to about 15 Å/min, greater than or equal to about 20 Å/min, greater than or equal to about 25 Å/min, greater than or equal to about 30 Å/min, greater than or equal to about 35 Å/min, greater than or equal to about 40 Å/min, greater than or equal to about 45 Å/min, greater than or equal to about 50 Å/min, greater than or equal to about 55 Å/min, greater than or equal to about 60 Å/min, greater than or equal to about 65 Å/min, greater than or equal to about 70 Å/min, greater than or equal to about 75 Å/min, greater than or equal to about 80 Å/min, greater than or equal to about 85 Å/min, greater than or equal to about 90 Å/min, greater than or equal to about 95 Å/min, greater than or equal to about 100 Å/min, greater than or equal to about 110 Å/min, greater than or equal to about 120 Å/min, greater than or equal to about 130 Å/min, greater than or equal to about 140 Å/min, greater than or equal to about 150 Å/min, greater than or equal to about 160 Å/min, or greater than or equal to about 170 Å/min, greater than or equal to about 180 Å/min, greater than or equal to about 190 Å/min, greater than or equal to about 200 Å/min, greater than or equal to about 210 Å/min, greater than or equal to about 220 Å/min, greater than or equal to about 230 Å/min, greater than or equal to about 240 Å/min, greater than or equal to about 250 Å/min, greater than or equal to about 260 Å/min, greater than or equal to about 270 Å/min, greater than or equal to about 280 Å/min, greater than or equal to about 290 Å/min, or greater than or equal to about 300 Å/min, or any range or value therein between.

Reference will now be made in detail to some specific embodiments contemplated by the present disclosure. While various embodiments are described herein, it will be understood that it is not intended to limit the present technology to the described embodiments. On the contrary, it is intended to cover alternatives, modifications, and equivalents as may be included within the spirit and scope of the technology as defined by the appended claims.

### EXAMPLES

The present invention will now be described in more detail by way of examples. It is, however, not intended to limit the scope of the present technology to the following examples. In the following description, each operation was conducted under conditions of room temperature (25° C.)/relative humidity of 40 to 50% RH unless otherwise stated.

### Materials and Methods

### Preparation of Polishing Compositions

TABLE 1
Silica Abrasive Particles Properties

| Abrasive | Average Primary | Mean Particle | Function- |
|---|---|---|---|
| Grains | Particle Size (nm) | Size (nm) | ality |
| 1 | 12 | 20 | Sulfonic |
| | | | Acid |
| 2 | 23 | 27 | — |
| 3 | 33 | 64 | — |
| 4 | 12 | 20 | — |

Abrasive grains 1 were obtained by chemically bonding MPS to the surface of colloidal silica through a dehydration condensation reaction, and then oxidizing a terminal thiol group with hydrogen peroxide.

Abrasive grains 4 are the abrasive grains 1 not surface-treated.

Abrasive grains 2 and 3 are the abrasive grains 4 having different particle sizes.

An average primary particle size can be calculated, for example, based on the specific surface area (SA) of the abrasive grains calculated by a BET method, and the density of the abrasive grains. An average secondary particle size (mean particle size) of abrasive grains can be measured, for example, by a dynamic light scattering method represented by a laser diffraction scattering method.

### <Average Primary Particle Size>

The average primary particle size was calculated based on a specific surface area of silica abrasive particles measured by a BET method with “Flow Sorb II 2300” manufactured by Micromeritics Corporation, and the density of the silica abrasive particles.

### <Mean Particle Size>

The mean particle size (average secondary particle size) of the silica abrasive particles was measured as a volume average particle size (volume-based arithmetic mean diameter; Mv) with a dynamic light scattering particle size/distribution measuring apparatus UPA-UTI151 (manufactured by NIKKISO CO., LTD.).

Polishing compositions comprising the abrasive particles shown in Table 1 were prepared by mixing (mixing temperature: about 25° C.; mixing time: about 20 minutes), with water, colloidal silica (e.g., having the properties shown in Table 1) as the abrasive grains, hydrogen peroxide as the oxidizer, benzotriazole (BTA) as the inhibitor (metal corrosion inhibitor), surfactant 1 and/or 2 (see Table 2 below), 2-hydroxy phosphonoacetic acid (HPAA) as acidic compound, KHCO₃ as the salt or citric acid as the pH adjusting agent, and pullulan as the polymer. The pH of the composition was adjusted by monitoring the pH while adding potassium hydroxide as the pH adjusting agent until the selected composition pH (pH=9.4) was reached. Some of the above-described components were not contained in some slurries, and “-” shown in the table means that the corresponding component was not added.

### pH Measurement

The pH of polishing compositions according to the present disclosure was determined using a Thermo-Fisher Scientific VSTAR94 pH Meter.

### Zeta Potential Measurement

Zeta potentials for various abrasive grains in polishing compositions according to the present disclosure were determined using a ZETASIZER® (Malvern Panalytical). The results are shown in Table 3. Zeta potential for various substrates polished using the polishing compositions according to the present disclosure may be determined using SurPASS™ 3 Zeta Potential Analyzer (Anton Paar GmbH).

### Polishing Composition Stability

Polishing composition stability was determined by measuring the change in particle size (D₅₀) after storage for 2 weeks in a capped bottle without stirring, at 55° C. Particle sizes (D₅₀) were measured by a light scattering method using a Horiba LA-950 laser diffraction analyzer (Horiba, Ltd.). For purposes of the present disclosure, particle stability is indicated by a ratio of the particle size after storage to the particle size before storage (n=D_{50 (after)}/D_{50 (before)}). “Good” particle stability indicates n<1.10, while “poor” particle stability indicates n≥1.10.

As used herein, and unless otherwise described, the term “D50” refers to the median diameter or the median value of the particle size distribution. In some embodiments, “D50” refers to the value of the particle diameter at 50% in the cumulative distribution. In some embodiments, “D50” refers to the median particle size (e.g., diameter) for a volume distribution. As used herein, and unless otherwise described, the term “D90” is the particle size (e.g., diameter) for a volume distribution at which 90% of the distribution lies below this size. Similarly, as used herein, and unless otherwise described, the term “D10” is the particle size (e.g., diameter) for a volume distribution at which 10% of the distribution lies below this size.

The stability of the polishing compositions is shown in the column of “Stability” of Table 2.

### Removal Rate Measurement

To determine polishing rates, the polishing compositions were applied to each of Ta (1000 Å), Cu (1500 Å), and Co (2000 Å) films deposited on silicon wafers having a thermal oxide layer derived from TEOS, using the following polishing conditions:
Polisher: 200 mm Polisher (Westech);
Polishing pad: Fujibo H800;
Conditioner: 3M Nylon brush;
Down force: 1.0 psi
Platen rotation: 110.0 rpm;
Head rotation: 105.0 rpm;
Slurry flow rate: 100.0 mL/min.

To assess the removal rates achieved by the polishing compositions, film thickness before and after polishing was measured using a Resmap Resistivity Mapping System (Creative Design Engineering, Inc.), for Ta, Cu, and Co films.

### Effect of Surfactant on Polishing Performance (Removal Rate and Selectivity)

To further assess the polishing performance of polishing compositions according to the present disclosure, the polishing compositions shown in Table 2 were prepared and their stability, removal rates for Ta, Co, and Cu, and removal rate selectivities were assessed according to the methods disclosed above. As shown in Table 2, polishing compositions comprising Abrasive grains 1 (oxidized MPS-modified silica; 12 nm) and either polyoxyethylene nonyl phenyl phosphate (Slurry G) or polyoxyethylene (10) oleyl ether phosphate (Slurry H) showed excellent Cu/Co selectivity (namely, low selectivity) (1.1 and 0.9, respectively), excellent Ta/Co selectivity (12 and 13, respectively), and good stability.

TABLE 2
Polishing Performance Versus Polishing Slurry Composition

| | | | Concentration, POU(wt. %) | | | | | |
|---|---|---|---|---|---|---|---|---|
| Slurry Composition | | | Slurry A | Slurry B | Slurry C | Slurry D | Slurry E | Slurry F |
| Component | Abrasive | 1 | 4.2 | — | — | — | 2.0 | 2.0 |
| | Grains | 2 | — | — | 4.2 | — | — | — |
| | | 3 | — | 4.2 | — | 2.9 | — | — |
| | | 4 | — | — | — | — | — | — |
| | pH Adjuster | KOH | 1.03 | 1.03 | 1.03 | 0.77 | 0.55 | 0.58 |
| | | (48 wt. %) | | | | | | |
| | Inhibitor | BTA | 0.04 | 0.04 | 0 04 | 0.03 | 0.02 | 0.02 |
| | Surfactant | UCON | 0.1 | 0.1 | 0.1 | — | — | — |
| | 1 | 50-400 | | | | | | |
| | | UCON | — | — | — | 0.1 | 0.1 | 0.1 |
| | | 50-2000 | | | | | | |
| | Surfactant | Ethfac | — | — | — | — | — | 0.1 |
| | 2 | 142W | | | | | | |
| | | Ethfac | — | — | — | — | — | — |
| | | NP-110 | | | | | | |
| | | Crodafos | — | — | — | — | — | — |
| | | OI0A | | | | | | |
| | Acidic | HPAA | 0.09 | 0.09 | 0.09 | — | — | — |
| | Compound | | | | | | | |
| | Salt | KHCO₃ | 0.11 | 0.11 | 0.11 | — | — | — |
| | pH Adjuster | Citric Acid | — | — | — | 0.24 | 0.17 | 0.17 |
| | Polymer | Pullulan | 0.03 | 0.03 | 0.03 | 0.03 | 0.02 | 0.02 |
| | Oxidizer | H₂O₂ | 2.8 | 2.8 | 2.8 | 2.8 | 2.7 | 2.7 |

| Stability | 2 wk.; | Good | Good | Good | Good | Good | Good |
|---|---|---|---|---|---|---|---|
| | 55° C. | | | | | | |
| Removal Rate (Å/min) | Ta | 229 | 141 | 270 | 155 | 112 | 115 |
| | Cu | 243 | 114 | 220 | 39 | 21 | 18 |
| | Co | 22 | 7 | 21 | 14 | 29 | 5 |
| Selectivity (RR Ratio) | Ta/Co | 10 | 20 | 13 | 11 | 4 | 23 |
| | Cu/Co | 11 | 16 | 10 | 0.3 | 0.7 | 3.6 |

TABLE 2
Polishing Performance Versus Polishing Slurry Composition

| | | | Concentration, POU(wt. %) | | | | |
|---|---|---|---|---|---|---|---|
| Slurry Composition | | | Slurry G | Slurry H | Slurry I | Slurry J | Slurry K |
| Component | Abrasive | 1 | 2.0 | 2.0 | — | — | — |
| | Grains | 2 | — | — | — | — | — |
| | | 3 | — | — | — | — | — |
| | | 4 | — | — | 2.0 | 2.0 | 2.0 |
| | pH Adjuster | KOH | 0.58 | 0.58 | 0.55 | 0.55 | 0.55 |
| | | (48 wt. %) | | | | | |
| | Inhibitor | BTA | 0.02 | 0.02 | 0.02 | 0.02 | 0.02 |
| | Surfactant | UCON | — | — | — | — | — |
| | 1 | 50-400 | | | | | |
| | | UCON | 0.1 | 0.1 | 0.1 | 0.1 | 0.1 |
| | | 50-2000 | | | | | |
| | Surfactant | Ethfac | — | — | 0.1 | — | — |
| | 2 | 142W | | | | | |
| | | Ethfac | 0.1 | — | — | 0.1 | — |
| | | NP-110 | | | | | |
| | | Crodafos | — | 0.1 | — | — | 0.1 |
| | | O10A | | | | | |
| | Acidic | HPAA | — | — | — | — | — |
| | Compound | | | | | | |
| | Salt | KHCO₃ | — | — | — | — | — |
| | pH Adjuster | Citric Acid | 0.17 | 0.17 | 0.17 | 0.17 | 0.17 |
| | Polymer | Pullulan | 0.02 | 0.02 | 0.02 | 0.02 | 0.02 |
| | Oxidizer | H₂O₂ | 2.7 | 2.7 | 2.7 | 2.7 | 2.7 |

| Stability | 2 wk.; | Good | Good | Poor | Poor | Poor |
|---|---|---|---|---|---|---|
| | 55° C. | | | | | |
| Removal Rate (Å/min) | Ta | 106 | 140 | 144 | 136 | 134 |
| | Cu | 10 | 10 | 7 | 10 | 13 |
| | Co | 9 | 11 | 5 | 22 | 22 |
| Selectivity (RR Ratio) | Ta/Co | 12 | 13 | 29 | 6 | 6 |
| | Cu/Co | 1.1 | 0.9 | 1.4 | 0.5 | 0.6 |

POU (Point of Use) in table indicates the time of polishing test (polishing used).
UCON 50-HB-400: polyalkylene glycol monobutyl ether CAS: 9038-95-3
UCON 50-HB-2000: polyalkylene glycol monobutyl ether CAS: 9038-95-3
Ethfac 142W: laureth-4 phosphate CAS: 39464-66-9
Ethfac NP-110: polyoxyethylene nonyl phenyl phosphate CAS: 51811-79-1
Crodafos O10A: polyoxyethylene (10) oleyl ether phosphate CAS: 39464-69-2

Compositions according to the present disclosure preferably have Ta/Co selectivities of greater than 10 (e.g., 11, 12, 13, 14, 15, etc.) and Cu/Co selectivities of close to 1 (e.g., 0.3 to 3 or 0.8 to 1.2, etc.) as their properties. As evidenced in Table 2, barrier polishing compositions comprising Abrasive grains 1 (oxidized MPS-functionalized; 12 nm) and either Crodafos O10A (polyoxyethylene (10) oleyl ether phosphate) or Ethfac NP-110 (polyoxyethylene nonyl phenyl phosphate) show good stability, good Ta/Co selectivity (>10), and good Cu/Co selectivity (0.9 to 1.1).

Besides, the following shall be noticed: When silica particles are present under a basic environment (having a pH of greater than 7.0, and a pH of 9.4 in the present example), their stability should be usually good as shown in the results obtained where Slurries B, C, and D are used. When silica particles having a very small average primary particle size were used, however, the stability was insufficient as shown in the results obtained where Slurries I, J, and K are used. This is probably because the phosphate ester-based surfactant having a polyoxyalkylene (POA) chain specifically adsorbed to the surfaces of the surface-unmodified abrasive grains having a small particle size, and therefore, the abrasive grains aggregated to become unstable. On the contrary, the stability was good when surface-modified anionic silica particles were used as the abrasive grains.

Meanwhile, if no phosphate ester is added (e.g., Slurry E), the Ta/Co selectivity is too low (e.g., 4). Addition of phosphate ester (e.g., Slurries F, G, H) inhibits Co removal and increases the Ta/Co selectivity to a value above 10. Nonetheless, the presence of particular phosphate esters (e.g., Slurry G (Ethfac NP-110), Slurry H Crodafos O10A)) reduces the Cu/Co selectivity to values near 1. Indeed, the phosphate esters tested in Slurry F (Ethfac 142W), Slurry G (Ethfac NP-110), and Slurry H (Crodafos O10A) appear to inhibit copper removal and cobalt removal to different degrees when anionically-modified small abrasive particles (e.g., Abrasive grains 1) are present, allowing tunable selectivities for Cu and Ta, relative to Co.

Further, if small, unmodified abrasive particles are used (e.g., Abrasive grains 4), such as in Slurries I, J, and K, the Ta/Co selectivity was too low (e.g., less than 10), and the Cu/Co selectivity is too far from 1 (e.g., 40% or 50% higher or lower than 1).

Without being bound to any particular theory, it is hypothesized that to achieve a low cobalt removal rate, relative to tantalum removal rate, a phosphate ester surfactant may increase the contact angle of deionized water on cobalt, thereby inhibiting access of the polishing composition to the cobalt surface and reducing the polishing rate. To achieve a ratio of the copper polishing rate (Å/min) to the cobalt polishing rate (Å/min) of 0.3 to 5, and the ratio of the tantalum polishing rate (Å/min) to the cobalt polishing rate (Å/min) of greater than or equal to 10, it is hypothesized that it is better the surfactant has a phosphate head group, an appropriate number of oxyalkylene groups such as EO groups (e.g., less than or equal to 25, 20, or 15, and greater than or equal to 5) and a hydrocarbon tail having greater than 6 (e.g., 7, 8, 9, 10, 11, 12, 13, 14, 15, 16, 17, 18, 19, 20, or greater) carbon atoms, as shown in Table 3 below.

TABLE 3
Polishing Performance Obtained by Different Surfactants

| | | MW | # EO | | | RR_{Ta} | RR_{Co} | | Contact | Zeta Potential |
|---|---|---|---|---|---|---|---|---|---|---|
| Slurry | Surfactant | (g/mol) | groups | Head Group | Hydrocarbon Tail | (Å) | (Å) | Ta/Co | Angle (°) | (mV) |
| F | Ethfac 142W | 460 | 4 | Phosphate | C₁₂₋₁₄ | 115 | 5 | 23 | 66 | −30.3 |
| | | | | | Straight chain | | | | | |
| G | Ethfac NP-110 | 700 | 9 | Phosphate | Nonyl phenyl | 106 | 9 | 12 | 8 | −28.9 |
| H | Crodafos O10A | 787 | 10 | Phosphate | Oleyl | 140 | 11 | 13 | 67 | −29.4 |

The contact angle was measured using DROP SHAPE ANALYZER—DSA25E, Kruss. The measurement of the contact angle may be conducted by dropping 5 μL of deionized water onto a substrate, and measuring the contact angle after 5 seconds with a contact angle measuring device.

In some embodiments, the polishing compositions have properties that the contact angle of water on a Co substrate having been polished using the polishing composition is less than or equal to 80°, less than or equal to 70°, less than or equal to 60°, less than or equal to 50°, less than or equal to 40°, less than or equal to 30°, less than or equal to 20°, or less than or equal to 10°. In some embodiments, the polishing compositions have properties that the contact angle of water on a Co substrate having been polished using the polishing composition is greater than or equal to 5°, greater than or equal to 10°, greater than or equal to 20°, greater than or equal to 30°, greater than or equal to 40°, greater than or equal to 50°, or greater than or equal to 60°.

While certain embodiments have been illustrated and described, it should be understood that changes and modifications may be made therein in accordance with ordinary skill in the art without departing from the technology in its broader aspects as defined in the following claims.

The compositions and methods illustratively described herein may suitably be practiced in the absence of any element or elements, limitation or limitations, not specifically disclosed herein. Thus, for example, the terms “comprising”, “including,” containing”, etc. shall be read expansively and without limitation. Additionally, the terms and expressions employed herein have been used as terms of description and not of limitation, and there is no intention in the use of such terms and expressions of excluding any equivalents of the features shown and described or portions thereof. It is recognized that various modifications are possible within the scope of the disclosure claimed. Thus, it should be understood that although the present disclosure has been specifically disclosed by preferred embodiments and optional features, modification and variation of the disclosure embodied therein herein disclosed may be resorted to by those skilled in the art, and that such modifications and variations are considered to be within the scope of this disclosure.

The disclosure has been described broadly and generically herein. Each of the narrower species and subgeneric groupings falling within the generic disclosure also form part of the methods. This includes the generic description of the methods with a proviso or negative limitation removing any subject matter from the genus, regardless of whether or not the excised material is specifically recited herein. The present technology is not to be limited in terms of the particular embodiments described in this application, which are intended as single illustrations of individual aspects of the present technology. Many modifications and variations of this present technology can be made without departing from its spirit and scope, as will be apparent to those skilled in the art. Functionally equivalent methods and apparatuses within the scope of the present technology, in addition to those enumerated herein, will be apparent to those skilled in the art from the foregoing descriptions. Such modifications and variations are intended to fall within the scope of the present technology. It is to be understood that this present technology is not limited to particular methods, reagents, compounds compositions or biological systems, which can, of course, vary. It is also to be understood that the terminology used herein is for the purpose of describing particular embodiments only, and is not intended to be limiting.

One skilled in the art readily appreciates that the present disclosure is well adapted to carry out the objects and obtain the ends and advantages mentioned, as well as those inherent therein. Modifications therein and other uses will occur to those skilled in the art. These modifications are encompassed within the spirit of the disclosure and are defined by the scope of the claims, which set forth non-limiting embodiments of the disclosure.

In addition, where features or aspects of the disclosure are described in terms of Markush groups, those skilled in the art will recognize that the disclosure is also thereby described in terms of any individual member or subgroup of members of the Markush group.

All references, articles, publications, patents, patent publications, and patent applications cited herein are incorporated by reference in their entireties for all purposes. However, mention of any reference, article, publication, patent, patent publication, and patent application cited herein is not, and should not be taken as, an acknowledgment or any form of suggestion that they constitute valid prior art or form part of the common general knowledge in any country in the world.

Other embodiments are set forth in the following claims.

1. A polishing composition, comprising:
abrasive grains comprising surface-modified anionic silica particles; and
a surfactant,
wherein the surfactant comprises a compound represented by the following formula (I):
[tail-Aₙ-O]ₘ—PO_{q}Hᵣ (I)
wherein the tail is alkenyl or alkylaryl, the alkenyl has 2 to 24 carbon atoms, alkyl of the alkylaryl has 1 to 24 carbon atoms, A is oxyalkylene, the alkylene has 1, 2, or 3 carbon atoms, n is 1 to 20, and m, q, and r are respectively 1, 3, 2; 2, 2, 1; or 3, 1, 0.

2. The polishing composition according to claim 1, wherein the silica particles have an average primary particle size of less than or equal to 30 nm.

3. The polishing composition according to claim 1, further comprising a metal corrosion inhibitor.

4. The polishing composition according to claim 1, wherein aryl of the alkylaryl is phenyl.

5. The polishing composition according to claim 1, wherein the surface-modified anionic silica particles are colloidal silica having an organic acid immobilized on the surface thereof.

6. The polishing composition according to claim 3, wherein the metal corrosion inhibitor comprises benzotriazole.

7. The polishing composition according to claim 1, comprising a polysaccharide.

8. The polishing composition according to claim 7, wherein the polysaccharide is glucan.

9. The polishing composition according to claim 8, wherein the glucan is a glucan.

10. The polishing composition according to claim 1, comprising an organic acid having one or more hydroxy groups and two or more carboxyl groups.

11. The polishing composition according to claim 10, having a pH of 7 to 10.

12. The polishing composition according to 1, wherein the surfactant is present in the polishing composition at a concentration of 0.01 wt. % to 0.3 wt. %.

13. The polishing composition according to claim 1, to be used for polishing a polishing object, wherein the polishing object comprises at least one of cobalt and copper, and tantalum.

14. The polishing composition according to claim 1, wherein the polishing composition is designed in such a manner that a ratio of a copper polishing rate (Å/min) to a cobalt polishing rate (Å/min) is 0.3 to 5, and that a ratio of a tantalum polishing rate (Å/min) to the cobalt polishing rate (Å/min) is greater than or equal to 10.

15. A polishing composition, comprising:
abrasive grains comprising surface-modified anionic silica particles; and
a surfactant,
wherein the surfactant comprises a compound represented by the following formula (I):
[tail-Aₙ-O]ₘ—PO_{q}Hᵣ (I)
wherein the tail is alkenyl or alkylaryl, the alkenyl has 2 to 24 carbon atoms, alkyl of the alkylaryl has 1 to 24 carbon atoms, A is oxyalkylene, the alkylene has 1, 2, or 3 carbon atoms, n is 1 to 20, and m, q, and r are respectively 1, 3, 2; 2, 2, 1; or 3, 1, 0, and
the polishing composition comprises a polysaccharide, and an organic acid having one or more hydroxy groups and two or more carboxyl groups, and has a pH of 7 to 10.

16. The polishing composition according to claim 1, further comprising polyalkylene glycol monoalkyl ether.
